(19) United States
(12) Patent Application Publication
(10) Pub. No.: US 2024/0202655 A1
(43) Pub. Date: Jun. 20, 2024

(54) SHIP ROUTE OPTIMIZATION

(71) Applicant: X Development LLC, Mountain View, CA (US)

(72) Inventors: Antoni Jordi Ballester, San Francisco, CA (US); Alexandre Szenicer, London (GB); Bertrand Louis Rene Delorme, San Francisco, CA (US); Yangli Hector Yee, San Francisco, CA (US); Julia Black Ling, Menlo Park, CA (US)

(21) Appl. No.: 18/463,842

(22) Filed: Sep. 8, 2023

Related U.S. Application Data
(63) Continuation of application No. PCT/US2023/030728, filed on Aug. 21, 2023.
(60) Provisional application No. 63/485,121, filed on Feb. 15, 2023.
(60) Provisional application No. 63/387,456, filed on Dec. 14, 2022.
(60) Provisional application No. 63/387,471, filed on Dec. 14, 2022.

(51) Int. Cl. G06Q 10/0835

(52) U.S. Cl. CPC G06Q 10/08355

(57) ABSTRACT

Methods, systems, and apparatus, including computer programs encoded on computer storage media, for determining elements of a shipping network. One of the methods includes obtaining environmental input data, wherein the environmental input data includes weather forecast data; providing the environmental input data to a circulation model; and providing output environmental condition from the circulation model to a machine learning model trained to generate a route for a ship.

### CROSS-REFERENCE TO RELATED APPLICATION

This application is a continuation of, and claims priority to pending International Patent Application No. US2023/030728, filed Aug. 21, 2023, which claims the benefit of U.S. Provisional Application No. 63/387,471, filed Dec. 14, 2022, U.S. Provisional Application No. 63/387,456, filed Dec. 14, 2022, and U.S. Provisional Application No. 63/485,121, filed Feb. 15, 2023, the contents of which are incorporated by reference herein.

### BACKGROUND

Ships navigate around the world for various purposes. Because of various factors, such as weather, engines, port wait times, among many others, ships can be delayed. Global maritime trade has increased significantly in the last decades, since many countries export products around the world in large volumes. Currently the shipping industry is a critical part of the global supply chain, accounting for over 80-90% of the global trade by volume. The shipping industry is consequently a highly competitive market, requiring shipping companies to improve efficiency and to reduce operating costs. In addition, shipping is a major contributor to climate change. In 2018 the International Maritime Organization (IMO) called for a 40% cut in greenhouse gas emissions across the global shipping fleet by 2030, and at least a 50% cut by 2050.

Shipping can contribute about 3% of global anthropogenic greenhouse gas emissions making it one of the major contributors to climate change. Reducing such emissions have become central to national efforts (e.g., United States, Japan, among others) to decarbonize global shipping. Some countries are targeting zero emissions by 2050.

### SUMMARY

In some implementations, one or more machine learning models operate on weather data (e.g., global weather forecast, satellite data, among others) and historical data (e.g., historical ship routes, historical weather) to generate an optimal ship route. One or more machine learning models can be combined with one or more ocean circulation models to generate optimal ship routes.

Ship route optimization can include the selection of the shortest time route, the most economical route, the most energy efficient route, the safest route, or a combination of those aspects. Route optimization can be performed on routes from departure to arrival port, intermediate routes, among others, e.g., depending on requirements of shipping company. Factors used to optimize ship routes can include time constraints, ship characteristics, safety considerations, geographic features, weather and sea conditions—e.g., waves and ocean currents. Route optimization allows for reduction in carbon and other greenhouse gas emissions, reduction in cost, improved safety, greater efficiency at port through time or arrival estimation and delay minimization, among others. In general, the global supply chain can be better managed and controlled by optimizing fleet routes.

Historically, shipping companies estimate their routes based on pilot charts of the most navigated routes, representing typical historical route patterns. The crew and captain of the ships can change speed and course along the route for different reasons such as adverse weather events, political disputes, restrictions, or prohibitions. However, this can introduce uncertainties due to human factors such as insufficient experience of the crew or the route planning crossing oceans with unknown weather and ocean conditions.

In some implementations, techniques include providing ship routing optimization software that updates information on the ship location, weather, ocean currents, or waves conditions. A route of a ship can be updated to take into account changes in ship navigation, the weather, and ocean forecasts.

Producing weather, ocean currents, and waves forecasts is typically demanding in terms of computational resources. Such computational constraints can prevent simulations from increasing a resolution of the weather and oceanic flows creating inaccuracies, such as inaccuracy in route optimization. Mixing of models (referred to as parameterization) can be used to approximate effects at small scales that cannot be resolved numerically, e.g., due to computational constraints. Parameterizations can be a large source of uncertainty for forecast models.

Some shipping routes to get from a first location to another location can be less efficient than others. For example, some routes can take longer or be more costly for a given ship to traverse, e.g., more fuel consumption, greater carbon emissions, greater travel time, among others. Complicating the problem is the ever-changing nature of the routes due to various factors, such as weather, currents, waves, among others, which can typically change from day to day or even hour to hour.

In some implementations, a control unit receives data from a ship, such as a desired location or current location of the ship. The control unit can model various routes using data from locations along one or more simulated routes. Based on comparing one or more simulated routes, the control unit can determine what route is optimal and send the route details. What route is optimal can depend on a specific requesting ship. For example, some ships or types of ship can prefer less wait time at ports while others can prefer less cost.

In some implementations, a Monte Carlo sampling approach is used to return distributions for modeling real world uncertainty or risks, such as adverse weather conditions. The control unit can use a Monte Carlo sampling approach to generate one or more simulated routes.

In general, the control unit can generate one or more distributions over one or more outcomes for ship routing. The control unit can account for real world effects, e.g., static or variable, such as distributions of arrival time, risk of loss of goods, delays in loading and unloading, among others.

Techniques described herein can be used for network design. For example, the techniques can be used to optimize a network for shipping routes given probabilistic behavior. The techniques can enable a network to tradeoff between multiple objectives, e.g., resiliency, efficiency, among others. In some implementations, the techniques are used for network monitoring. For example, the techniques can be used to forecast network performance in operation to see how it will be affected by weather systems, potential port delays, among other factors.

Techniques can provide unbiased distributional estimates, e.g., with reasonable compute and time bounds, of various parameters for shipping, including arrival time, probability of loss of goods, fuel consumption, among others.

In some implementations, a ship route is represented by a graph between ports. In some implementations, a ship route is represented, using Monte Carlo sampling, or other sampling method, down to, e.g., meters of precision along a route depending on available compute power. Scenarios can be modelled, e.g., loading a cargo amount on to one ship and then have that ship go to a hub and split the cargo into one or more other ships. The techniques described herein could provide decision support distributions of possible outcomes for a ship route planner to use in determine a route for a ship to take.

In some implementations, a control unit generating a route for a ship obtains historical data to help model realistic distributions for routes. For example, the control unit can obtain data indicating port loading and unloading delays, probability of loss of goods due to weather, among others.

In some implementations, the control unit performs operations including a random walk over a graph of possible routes and goods. In some implementations, the control unit uses rejection sampling or a greedy algorithm to obtain a feasible solution. In some implementations, the control unit uses integer linear programming (ILP) or other algorithms to learn possible modes over a distribution. The control unit can still sample nearby paths to estimate an uncertainty surrounding a route. By modelling a problem probabilistically, the control unit can model counter factual outcomes like what if a canal was closed or if a port is being shut down, among others. The control unit can construct a decision support tool for a planner to help foresee possible risks associated with one or more network configurations.

In some implementations, the control unit can use random sample outcomes with deep learning. The deep learning can be used to reduce computation of long path searches or as importance samplers to guide paths towards better outcomes.

In some implementations, the control unit uses a value network. For example, a control unit can use a value network that includes one or more objectives that are being optimized for parameters, such as distance along a full path. The distance along a full path, or other parameters, can be pre-cached or compressed in a network, e.g., because state space is too large to represent directly. For example, with a plurality of different weather variables, thousands of intermediate nodes in the path, state space for determining a route can be larger than available space on a given computer memory of the control unit. In some implementations, different optimization objective functions are used to tradeoff between network robustness and performance.

Ships navigate around the world for various purposes. Because of various factors, such as weather, engines, port wait times, among many others, ships can be delayed. Some routes to get from a first location to another location can be less efficient. For example, some routes can take longer or be more costly for a given ship to traverse. Complicating the problem is the ever changing nature of the routes due to the various factors mentioned—e.g., weather, waves, current, other ships, among others-which typical change from day to day or even hour to hour. A fleet of vessels with varying capacity and speed can be used.

In some implementations, a control unit improves routing of shipping vessels by processing factors such as weather and ocean conditions among others that influence ship travel times and energy consumption. The control unit can find a best route for a fleet of ships transporting goods across a network of ports, taking into account the demands of those ports, limited capacity of the ships, and the time the ships take to navigate between ports.

In some implementations, techniques described herein include three components: (i) ship route (or voyage) optimization, (ii) ship fleet network optimization, and (iii) evaluation of network performance. For example, ship route optimization can include optimizing an efficiency of a single ship operation. A voyage profile can be chosen that leverages weather and ocean information from high-resolution models to make decisions about a ship route and speed. This can ensure just in time arrival or reduced fuel consumption. Single ship optimization can include other applications, such as safety or hull cleaning recommendations.

Ship fleet network optimization can include robust optimization that takes into account optimized ship routes, a ship fleet size or composition, and services and markets to serve. Other constraints that can be used for optimization can include port capacities or services, bunker purchasing, CII compliance or other regulations, or labor cost considerations. Ship fleet network optimization can generate a robust and resilient ship fleet network that provides, at least one or more of, cargo routing, fleet deployment, and scheduling of a fleet.

Evaluation of network performance can include analyzing either a current, or historical, optimized ship fleet network and evaluating whether the network is optimized, e.g., operates according to defined thresholds or compared to one or more other standard networks. The evaluation can be performed under nominal or off-nominal conditions, including weather delays, port congestion, or onboarding/offboarding times. Evaluation can include counterfactual analysis for rare events such as port or canal closures.

The techniques described herein can combine one or more components of optimization or factor analysis. Combinations can allow for planning future improvements and expansions of shipping networks or fleet composition or operation using scenario analysis. For example, a shipping network can be optimized for the adoption of green fuel or reduced power consumption by considering which ports provide alternative green fuels, such as low carbon fuels, hydrogen, ammonia, methane, or biofuels. A shipping network can be optimized using data indicating which routes are most amenable to alternative power. Furthermore, scenarios or recommendations on how to adopt green fuel or reduced power consumption within a network without disrupting service can be provided.

In general, one aspect of the subject matter described in this specification can be embodied in methods that include the actions of obtaining environmental input data, wherein the environmental input data includes weather forecast data; providing the environmental input data to a circulation model; and providing output environmental condition from the circulation model to a machine learning model trained to generate a route for a ship.

Other implementations of this aspect include corresponding computer systems, apparatus, computer program products, and computer programs recorded on one or more computer storage devices, each configured to perform the actions of the methods. A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions.

The foregoing and other implementations can each optionally include one or more of the following features, alone or in combination. In some implementations, actions include obtaining second environmental input data; determining the second environmental input data is different from the previously obtained environmental input data; and updating, using the second environmental input data, the route for the ship. In some implementations, actions include providing historical data to the machine learning model, wherein the machine learning model is trained to generate one or more candidate shipping routes, and wherein the one or more candidate shipping routes include the route for the ship. In some implementations, the historical data includes (1) historical shipping routes and (2) historical weather conditions.

In some implementations, the environmental input data includes data obtained from one or more satellites. In some implementations, the environmental input data includes wave height forecasts. In some implementations, the machine learning model includes processes to generate one or more values of a cost function for one or more candidate routes, wherein the one or more candidate routes includes the route for the ship.

In general, another aspect of the subject matter described in this specification can be embodied in methods that include the actions of generating simulated routes from a first location to a second location, including a first simulated route under a first environmental condition and a second simulated route under a second environmental condition; generating an uncertainty score for each of the simulated routes; comparing a first uncertainty score of the first simulated route and a second uncertainty score of the second simulated route; determining, using the comparison, an optimal simulated route from the simulated routes; and providing the optimal simulated route to a ship for traversing a portion of water.

Other implementations of this aspect include corresponding computer systems, apparatus, computer program products, and computer programs recorded on one or more computer storage devices, each configured to perform the actions of the methods. A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions.

The foregoing and other implementations can each optionally include one or more of the following features, alone or in combination. In some implementations, generating the uncertainty scores includes generating two or more uncertainty distributions, including a first uncertainty distribution using data representing the first environmental condition and a second uncertainty distribution using data representing the second environmental condition; and combining a portion of the two or more uncertainty distributions to generate a combined uncertainty distribution. In some implementations, actions include generating, using a combined uncertainty distribution generated using data representing the first environmental condition along a portion of the first simulated route, the first uncertainty score; and generating, using a combined uncertainty distribution generated using data representing the second environmental condition along a portion of the second simulated route, the second uncertainty score.

In some implementations, generating the uncertainty scores includes obtaining one or more values representing environmental conditions from an ocean model. In some implementations, generating the first uncertainty score includes obtaining one or more values representing the first environmental condition within an ocean region traversed by the first simulated route from an ocean model; and generating the second uncertainty score includes obtaining one or more values representing the second environmental condition within an ocean region traversed by the second simulated route from the ocean model.

In some implementations, the first location and the second location represent sea ports. In some implementations, actions include obtaining initial data from the ship prior to generating the simulated routes from the first location to the second location. In some implementations, the initial data includes data indicating the first location to the second location. In some implementations, the initial data includes route preferences of the ship. In some implementations, the initial data includes details of the ship. In some implementations, generating the uncertainty scores includes obtaining uncertainty data representing at least one of (1) one or more wait times or (2) weather events; and using the uncertainty data to generate the uncertainty scores.

In some implementations, generating simulated routes from the first location to the second location includes determining a path along water that connects the first location to the second location; and wherein generating the uncertainty scores includes predicting current or weather events along at least a portion of the path. In some implementations, predicting current or weather events along at least the portion of the path includes sampling from a starting distribution representing potential current or weather events along the portion of the path. In some implementations, sampling from the starting distribution representing potential current or weather events along the portion of the path includes sampling from the starting distribution using a Monte Carlo method for sampling distributions.

In general, another aspect of the subject matter described in this specification can be embodied in methods that include the actions of generating simulated shipping routes, including a first simulated route under a first environmental condition and a second simulated route under a second environmental condition; generating an uncertainty score for each of the one or more simulated shipping routes; determining, using the uncertainty scores, (1) a first ship to traverse the first simulated route of the simulated shipping routes and (2) a second ship to traverse the second simulated route of the simulated shipping routes; generating two or more candidate networks, wherein a first candidate network of the two or more candidate networks includes an indication of (1) the first ship to traverse the first simulated route and (2) the second ship to traverse the second simulated route; comparing the first candidate network and another candidate network of the two or more candidate networks under two or more different environmental conditions; determining, using the comparison, an optimal candidate network of the two or more candidate networks; and providing data indicating the optimal candidate network to the one or more ships.

Other implementations of this aspect include corresponding computer systems, apparatus, computer program products, and computer programs recorded on one or more computer storage devices, each configured to perform the actions of the methods. A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions.

The foregoing and other implementations can each optionally include one or more of the following features, alone or in combination. In some implementations, the two or more different environmental conditions are generated using an ocean model that predicts current or weather events. In some implementations, the simulated shipping routes include one or more shipping ports. In some implementations, actions include determining cargo to be transported by the first ship and the second ship.

In some implementations, actions include obtaining data from the first ship prior to determining the first ship to traverse the first shipping route of the one or more simulated shipping routes. In some implementations, the data obtained from the first ship includes data indicating one or more locations along the first shipping route. In some implementations, the data obtained from the first ship includes route preferences of the first ship. In some implementations, generating an uncertainty score for each of the one or more simulated shipping routes includes generating an uncertainty score for the first simulated route including generating one or more distributions representing the first environmental condition of the first simulated route. In some implementations, the first environmental condition of the first simulated route include wait times at port or weather events.

In some implementations, actions include generating one or more distributions representing an effect of environmental conditions of the two or more different environmental conditions on the first simulated route and the second simulated route. In some implementations, actions include comparing a previously determined network and the optimal candidate network, wherein the previously determined network includes one or more of (1) a route of the first ship different than the first simulated route or (2) a route of the second ship different than the second simulated route. In some implementations, actions include performing the comparison of the previously determined network and the optimal candidate network under the two or more different environmental conditions. In some implementations, the two or more different environmental conditions include nominal and off-nominal conditions.

In general, another aspect of the subject matter described in this specification can be embodied in methods that include the actions of obtaining shipping network data from a shipping network; providing the shipping network data to one or more machine learning models configured to predict future shipping network data under two or more environmental conditions; and determining, using output of the one or more machine learning models, one or more actions to perform in the shipping network.

Other implementations of this aspect include corresponding computer systems, apparatus, computer program products, and computer programs recorded on one or more computer storage devices, each configured to perform the actions of the methods. A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions.

The foregoing and other implementations can each optionally include one or more of the following features, alone or in combination. In some implementations, actions include generating an agent-based model of the shipping network, wherein each ship of the shipping network is represented as an agent in the agent-based model, and wherein the agent-based model includes dynamic modeling of environmental conditions. In some implementations, determining one or more actions to perform in the shipping network includes performing mixed-integer programming using the output of the one or more machine learning models.

In some implementations, actions include determining the one or more actions to perform in the shipping network using (1) heuristics, (2) mixed-integer programming, and (3) an agent-based model of the shipping network. In some implementations, obtaining shipping network data is in response to detecting a condition within the shipping network. In some implementations, the condition within the shipping network represents a ship of the shipping network being delayed.

In some implementations, actions include generating one or more candidate modifications to the shipping network. In some implementations, the one or more candidate modifications include modifying one or more routes for ships of the shipping network. In some implementations, actions include identifying routes of a set of the ships of the shipping network to modify using heuristics. In some implementations, actions include determining modifications of the routes of the set of the ships of the shipping network using mixed-integer programming and an agent-based model of the shipping network. In some implementations, actions include obtaining heuristic data indicating a modification for a first ship of the ships of the shipping network; and wherein generating the one or more candidate modifications to the shipping network includes using the heuristic data indicating the modification for the first ship of the ships of the shipping network.

In some implementations, determining the one or more actions to perform in the shipping network includes providing a user interface to a user device; and obtaining user input indicating the one or more actions to perform in the shipping network. In some implementations, actions include performing the one or more actions in the shipping network. In some implementations, performing the one or more actions in the shipping network includes transmitting a signal to one or more computing elements controlling a ship in the shipping network. In some implementations, the signal is configured to reroute the ship.

In general, another aspect of the subject matter described in this specification can be embodied in methods that include the actions of obtaining weather data indicating a state of weather in the world; obtaining shipping network data indicating a state of a shipping network; and providing the weather data and the shipping network data to one or more trained machine learning models configured to generate a recommendation for a vessel of the shipping network.

Other implementations of this aspect include corresponding computer systems, apparatus, computer program products, and computer programs recorded on one or more computer storage devices, each configured to perform the actions of the methods. A system of one or more computers can be configured to perform particular operations or actions by virtue of having software, firmware, hardware, or a combination of them installed on the system that in operation causes or cause the system to perform the actions. One or more computer programs can be configured to perform particular operations or actions by virtue of including instructions that, when executed by data processing apparatus, cause the apparatus to perform the actions.

The foregoing and other implementations can each optionally include one or more of the following features, alone or in combination. In some implementations, providing the weather data and the shipping network data to one or more trained machine learning models configured to generate the recommendation for the vessel of the shipping network includes predicting one or more estimated times of arrival for one or more vessels in the shipping network. In some implementations, actions include obtaining data indicating a generated recommendation from the one or more trained machine learning models, wherein the generated recommendation indicates a recommended berth for the vessel of the shipping network.

In some implementations, actions include obtaining data indicating a generated recommendation from the one or more trained machine learning models, wherein the generated recommendation indicates a recommended schedule option for the vessel of the shipping network.

This specification uses the term “configured to” in connection with systems, apparatus, and computer program components. That a system of one or more computers is configured to perform particular operations or actions means that the system has installed on its software, firmware, hardware, or a combination of them that in operation cause the system to perform those operations or actions. That one or more computer programs is configured to perform particular operations or actions means that the one or more programs include instructions that, when executed by data processing apparatus, cause the apparatus to perform those operations or actions. That special-purpose logic circuitry is configured to perform particular operations or actions means that the circuitry has electronic logic that performs those operations or actions.

The subject matter described in this specification can be implemented in various implementations and may result in one or more of the following advantages. For example, techniques can enable ships to travel routes they would not previously have traveled. A control unit or computer processor can be used to implement the techniques described herein. The techniques can enable time savings on shipping lanes. The techniques can reduce the greenhouse gas emissions of sea going freight carriers by optimizing paths of the ships. The techniques can shorten route times and thereby shorten the amount of carbon based fuel used to power a given ship over the course of the route. By reducing wait times, the techniques can similarly reduce pollution from idling of ships.

Advantageous implementations can include one or more of the following features. For example, systems described in this document can use one or more machine learning models to predict shipping network events. Using predictions, systems can predict optimized future courses of action and provide recommendations, or automatically perform recommended actions that can reduce emissions or reduce fuel consumption.

The details of one or more implementations of the subject matter described in this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 shows an example process for ship route optimization.

FIG. 2 is a diagram showing an example of a system for ship network optimization.

FIG. 3 is a diagram showing an example of a generated distributions for wait times at a port.

FIG. 4 is a flow diagram illustrating an example of a process for ship network optimization.

FIG. 5 is a diagram showing an example of a system for ship network optimization.

FIG. 6A is a diagram showing an example of voyage optimization.

FIG. 6B is a diagram showing an example of an impact of weather on a network for shipping.

FIG. 6C is a diagram showing an example of a ship network resilient to disruptions.

FIG. 6D is a diagram showing an example of optimization of shipping networks.

FIG. 6E is a diagram showing an example of elements of decarbonization for shipping networks.

FIG. 7 is a flow diagram illustrating an example of a process for ship network optimization.

FIG. 8 is a diagram showing a system for selecting optimal shipping routes in a shipping network.

FIG. 9 and FIG. 10 show example representation of recourse options

FIG. 11A-C show example user interfaces for representing shipping optimizations.

FIG. 12 shows an example workflow for generating berth allocations for one or more ships.

FIG. 13 shows an example workflow for generating tramp scheduling for one or more ships.

FIG. 14 shows an example user interface.

Like reference numbers and designations in the various drawings indicate like elements.

### DETAILED DESCRIPTION

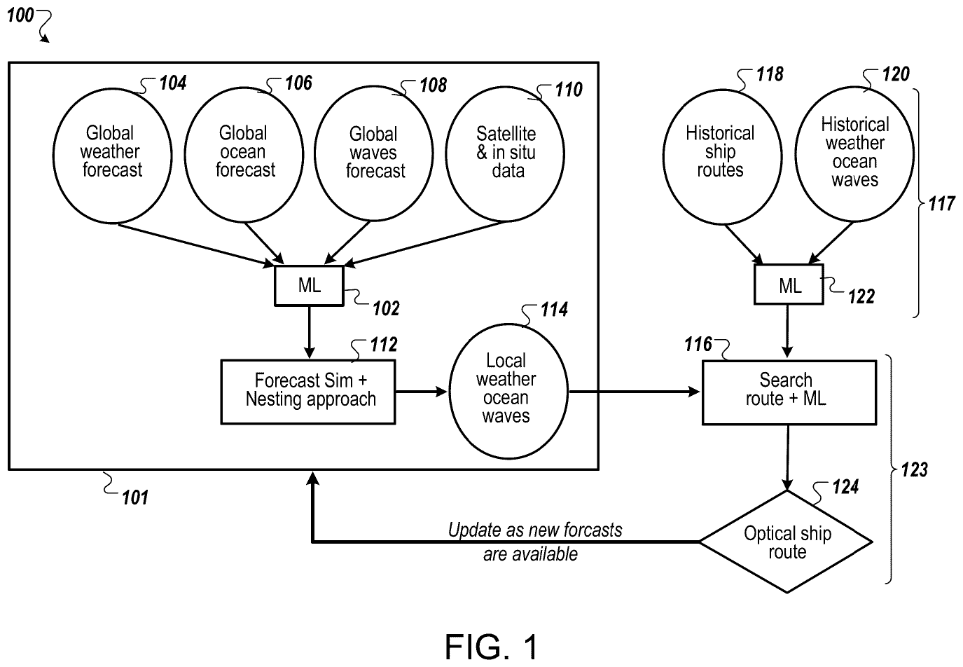

FIG. 1 shows an example process 100 for ship route optimization. In some implementations, the process 100 is performed by one or more electronic systems, such as computing devices. In general, the process 100 uses one or more machine learning models operating on weather data (e.g., global weather forecast, satellite data, among others) and historical data (e.g., historical ship routes, historical weather) to generate an optimal ship route 124.

The process 100 includes three components: (1) data-driven forecasts 101, (2) historical ship routes analysis 117, and (3) ship route search algorithm 123. Rectangles represent processes (e.g., algorithms, model simulations, among others), circles represent data (e.g., from observations, algorithms, models, among others), and the rhombus represents an optimal ship route 124 generated by the process 100.

For the data-driven forecast 101, a system implementing the process 100 can use an approach called “nesting” to go from global forecasts to local ones centered on a location of a ship (e.g., nesting 112). Data from global forecasts (e.g., global weather forecast 104, global ocean forecast 106, global wave forecast 108) provide large-scale conditions to local forecasts through boundaries and initial conditions. Local forecasts can run at a higher spatial resolution than global forecasts allowing for a better representation of small-scale processes. This can mitigate computational requirements of forecast simulations while keeping maximum accuracy.

In some implementations, different levels of “nesting” are used. For example, nesting levels can include global, regional, and local forecasts. As described herein, depending on implementation, forecasts can be made more accurate and less computationally expensive, e.g., using one or more machine learning (ML) methods. For example, a ML model-such as the ML model 102—can correct initial and boundary conditions from a global forecast based on available satellite and in situ observational data 110 before computing local forecasts. In some implementations, a ML model, such as the ML model 102, is used to tune or replace mixing parametrizations, correct local forecast simulations based on historical biases as a post-processing tool, or accelerate forecasts through resolving partial differential equations with deep learning methods and upscaling. Local weather, ocean and waves forecasts (e.g., forecast 114) provided by the ML model 102 can be used by the ship route search algorithm 123.

In some implementations, the process 100 includes one or more operations performed by an ocean circulation model. For example, the ML model 102 can be a form of ocean circulation model. In some implementations, an ocean circulation model solves partial differential equations using data as initial and boundary conditions—e.g., weather forecasts, satellite data, sensor data, among others. In some implementations, the ocean circulation model is enhanced. For example, the ocean circulation model can be enhanced using techniques from machine learning, such as Bayesian optimization, among others. Enhanced can refer to modifying some parameters of a physical model, e.g., the ocean circulation model, using local observations, e.g., local weather or weather sensor data.

The historical ship routes analysis 117 determines how forecasted weather, ocean currents, and waves affect ship movement. The historical ship routes analysis 117 combines data along historical ship routes (e.g., ship routes 118 and weather 120) with ML methods (e.g., ML model 122). The ship speed and trajectory can be influenced by one or more parameters, including its engine power and direction, which is set by the captain and crew. One or more parameters can be used by an implementing system to determine fuel consumption and gas emissions. Ship properties, such as cargo weight and environmental conditions (weather, ocean currents, waves, among others) can increase a complexity of a corresponding model of ship routes. Using data based on historical routes for one or more ships (e.g., a specific or general ship), the ML model 122 can predict a ship's performance in all conditions. The ML model 122 can be the same or different from the ML model 102, depending on implementation.

The ship route search algorithm 123 combines local forecasts provided by the data-driven forecasts component 101 and the ship's performance provided by the historical ship routes analysis 117. The ship route search algorithm 123 generates a result that includes a selection of the most appropriate (e.g., optimal) route for a ship to navigate from a departure port to a destination port. In some implementations, the ship route search algorithm 123 minimizes a cost function representing one or more of a total time, fuel consumption, gas emissions, among other parameters.

In some implementations, the ship route search algorithm 123, including search algorithm 116 (e.g., one or more trained ML models), determines one or more constraints on the solution. For example, the ship route search algorithm 123 can determine a first constraint as a maximum time representing a maximum time that a given ship can take to complete the route. For another example, the ship route search algorithm 123 can determine a constraint on ship motion, e.g., excessive motion due to wind or waves that may cause damage or cargo loss need to be avoided for safety purposes. For another example, the ship route search algorithm 123 can determine a constraint on speed using known speed restrictions stipulated by regulations. For another example, the ship route search algorithm 123 can determine a constraint on an area of travel using known areas of political conflicts or recorded piracy incidents.

In some implementations, the ship route search algorithm 123 includes one or more ML models. ML methods can be used to improve (or even replace) the ship route search algorithm 123. To reduce an uncertainty of forecasts, an optimal route can be iteratively updated each time new forecasts are available taking into account a last known location of the ship. One or more ML models can be trained by an implementing system to provide accurate output. For example, the ML model 102 can be trained to generate local weather forecast 114 using ground truth data of actual local weather and input data of global forecasts, satellite data, among others. The model 122 can be trained to generate ship performances using known ship performances as ground truth data and historical ship routes and weather as input data. The model 116 can be trained to generate one or more optimal ship routes for one or more ships using known optimal ship routes (e.g., generated by a more powerful, resource intensive, process, or manual process) as ground truths and one or more of data-driven forecasts or historical ship routes analysis as input data.

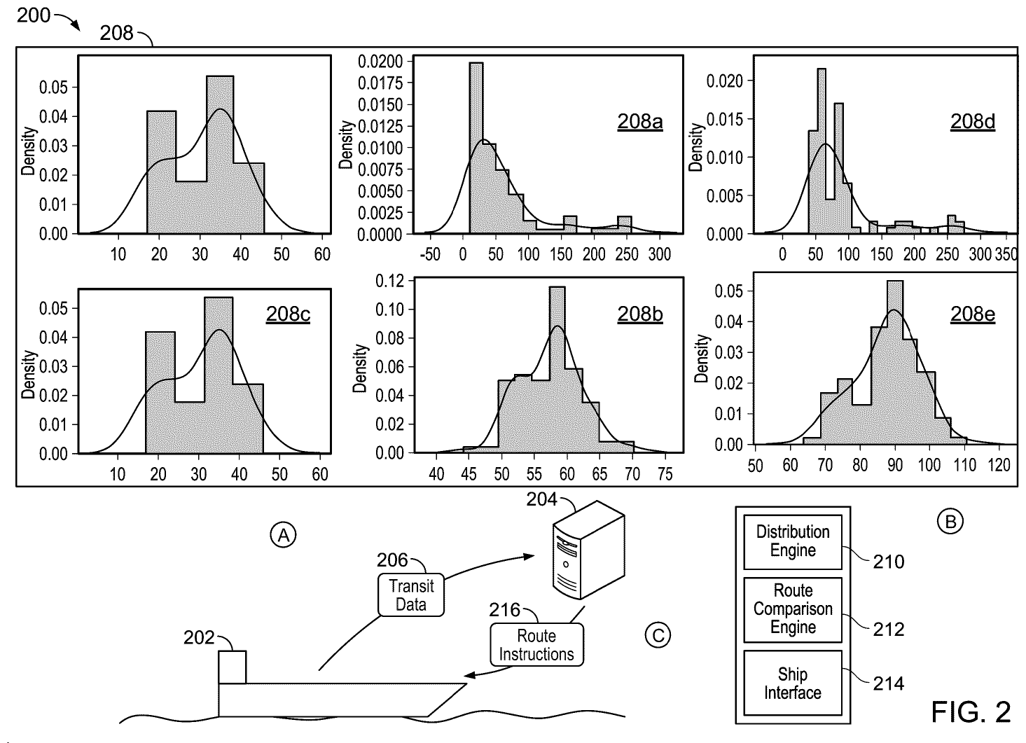

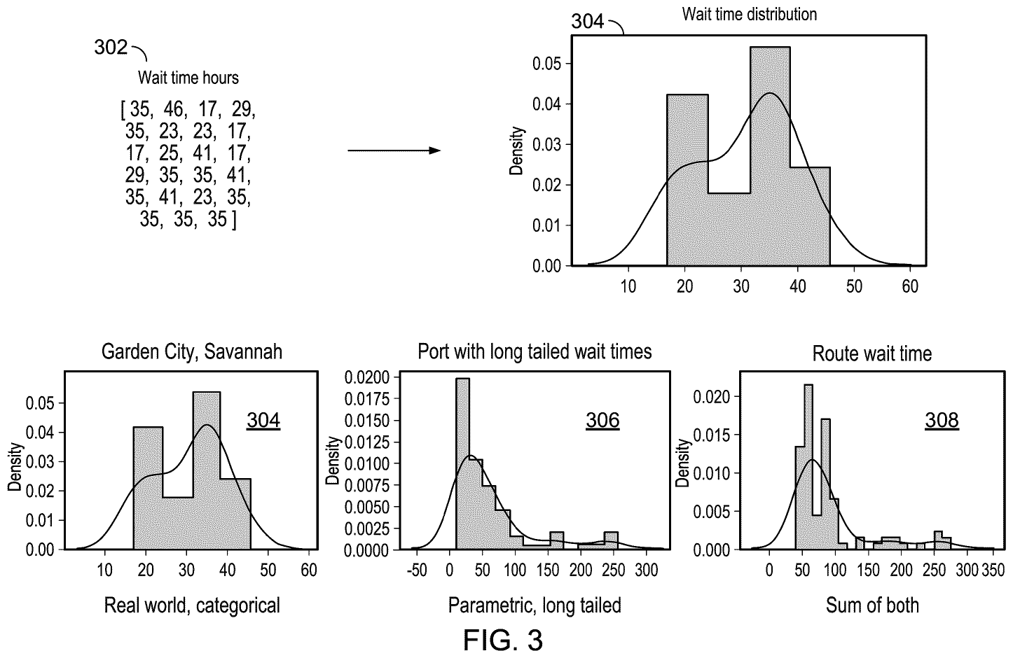

FIG. 2 is a diagram showing an example of a system 200 for ship network optimization. The system 200 includes a ship 202 and a control unit 204. The system 200 shows an example of the control unit 204 using generated distributions for wait times at a port, as shown in FIG. 3, to determine one or more simulated routes and providing route instructions 216 to the ship 202. In general, a ship network can include vessels, ports, and routes for vessels to traverse between the ports. The network can indicate a timing for traversal and indication of which vessel traverses which route to satisfy shipping needs—e.g., cargo delivery, among others.

In some implementations, the system 200 improves resiliency of optimized networks. For example, the system 200 can obtain indications of uncertainty from different data sources, e.g., historical leg times, ocean conditions, demand of cargo, among others. The system 200 can use indications of uncertainty when optimizing and generating a route for a ship, such as ship 202. Uncertainty can be represented as distributions or histograms. Uncertainty from historical leg times can represent an uncertainty in how long a journey from a starting point to one or more other points, such as ports, will take. As an illustrative example, one route may take 10 hours but has, historically, taken as long as 20 hours. Although 10 hours is more common, the system 200 can account for the possibility of longer leg times in determining whether to use that route or to use a different route—e.g., using a different route that takes 12 hours, but the range of possible elapsed times is less than another route. Uncertainty can similarly be a result of weather conditions or demand for cargo. For example, inclement weather can increase leg times along a route—e.g., making routes that pass through areas with a probability of a level of inclement weather less resilient than areas without a probability of that level of inclement weather. Demand for cargo can adjust a carrying capacity of a ship which can affect a speed or storm resiliency of the ship. In general, uncertainties can affect one another which can make accurate generation of uncertainties difficult or processor intensive.

In stage A, the ship 202 provides transit data 206. The transit data can include an indication of a current location of the ship 202, a destination for the ship 202, preferred routes of the ship 202, route preferences, among others. The control unit 204 obtains the transit data 206. The control unit 204 generates one or more distributions shown in item 208 and shown in more detail in FIG. 3.

In some implementations, the control unit 204 obtains a set of one or more vessels and a list of to-do items for the one or more vessels. The to-do items can include ports to be visited or cargo to be delivered. Using data indicating the set of one or more vessels and the list of to-do items, the control unit 204 can generate one or more routes. The control unit 204 can subject the one or more routes to simulated weather or other simulated conditions e.g., using one or more machine learning models trained using historical data—e.g., historical weather data, delay at ports over months or years, particular vessel transit time, among others. The control unit 204 can generate a distribution of metrics using the results of one or more routes and vessels on the routes. The techniques shown in FIG. 2 can help account for long statistical tails in route optimizations of one or more vessels—e.g., preferring a route with a higher mean wait time but lower maximum wait time.

In stage B, the distribution engine 210 of the control unit 204 can be used to generate one or more of the distributions in item 208. The generated distributions can be used by the route comparison engine 212 to determine what route is optimal for the ship 202. The route comparison engine 212 can generate uncertainty scores representing one or more uncertainty distributions from the distribution engine 210 and compare the uncertainty scores to determine an optimal route. An optimal route can represent a route that is the most resilient to disruptions e.g., minimizing risk of long leg times, inclement weather, port wait times, among other parameters described herein.

In some implementations, the route comparison engine 212 combines distributions. For example, for distributions that indicate time spent at ports along a given route, the route comparison engine 212 can combine all distributions along the route to generate a single distribution indicating a total wait time at ports over the course of the entire or a portion of a route. The route comparison engine 212 can then determine what route is optimal based on, e.g., preferences of the ship 202, standard preferences for reducing time or pollution, saving fuel, among others. In some implementations, the route comparison engine 212 determines an average wait time or other parameter based on one or more generated distributions to compare between one or more generated distributions.

In some implementations, the control unit 204 processes port delay data. For example, the ship 202 can have a schedule indicating one or more ports to visit (e.g., port A, port B, and port C). The control unit 204 can obtain historical data on port delays for the one or more ports. The control unit 204 can generate a distribution for each of the ports based on the obtained historical data, e.g., indicating the distribution of wait times at the given port represented in the historical data. The control unit 204 can take samples, indicating a specific delay, from each of the distributions of port delays and sum the delays to generate a possible delay total for an entire route. The control unit 204 can perform multiple sampling of the distributions to generate multiple possible delay totals for the entire route. The control unit 204 can generate a total delay time distribution indicating the distribution of those total delays.

In some implementations, the control unit 204 obtains additional data and uses the additional data for combining one or more distributions. For example, other variables can affect a travel time for a ship, such as the ship 202. The control unit 204 can obtain historical data for weather between ports, e.g., port A and B. The weather can include a distribution of recorded wave heights. Weather can impact a ship's speed. The amount of impact can depend on the size, shape, speed, or cargo of the ship. Using additional data, such as weather data, the control unit 204 can generate a distribution of travel time for a ship, at one or more engine power levels, over a portion of a route. For example, the control unit 204 can sample from the weather data across a portion of the route to generate multiple possible weather effects on the time. The control unit 204 can incorporate a distribution indicating travel time in a sampling procedure for port delays or other distribution. For example, the control unit 204 can combine the effect of weather and port delays to get a single distribution for a ship's travel time over a route. The control unit 204 can incorporate any number of variables relevant to a travel time of the ship in this way. However, in general, increasing the number of variables also increases a number of samples needed to accurately represent a resulting distribution. To make sampling and prediction efficient, the control unit 204 can use a subset of variables effecting travel times—e.g., weather and port delays.

In some implementations, one or more values of uncertainty distributions are used by the system 200 to determine one or more routes that are resilient. For example, the distribution engine 210 can determine, using one or more data sources of uncertainty, e.g., port data, historical ship journey data, weather data, among others, one or more values including one or more of range, interquartile range, standard deviation, or variance. Range can include a difference between a highest and lowest value within an uncertainty distribution. Interquartile range can include a range of a middle half of an uncertainty distribution. Standard deviation can include an average distance from the mean of an uncertainty distribution. Variance can include an average of squared distances from the mean of an uncertainty distribution.

Uncertainty distributions can be obtained from one or more data sources. For example, an uncertainty distribution can be obtained using ocean conditions from an ocean model, such as an ocean circulation model or enhanced ocean circulation model. Water ways used for routes can have average conditions and non-average conditions. Some water ways, e.g., areas of ocean, can be more volatile or likely to experience unusually harsh or disruptive weather. In some implementations, the system 200 determines one or more values along a route indicating uncertainty of water way conditions along the route. For example, a route can pass through a first region of ocean. The system 200 can obtain an uncertainty distribution from an ocean model for that first region, e.g., indicating an uncertainty of inclement weather. In some implementations, the system 200 combines uncertainty distributions along a route. For example, the distribution engine 210 can combine the uncertainty weather distribution from a first region with one or more other regions along a route to obtain a complete weather uncertainty distribution for the route.

In some implementations, one or more machine learning models are used with one or more ocean models to determine how different ocean conditions can affect leg times, among other shipping values of interest. For example, one or more models can be trained to generate a distribution of leg times between a first port and a second port for a ship that passes through one or more regions of water that can be modeled using one or more ocean models and models that determine a ship speed or other effect on the ship based on weather conditions. For example, in a storm, a route can take longer than when there is no storm. Some ships can be delayed longer by a given storm—e.g., smaller boats or boats with less cargo. The distribution engine 210 can obtain details of one or more ships to generate distributions for the given ships. For example, the distribution engine 210 can obtain details of the ship 202 and use the details of the ship 202 to generate one or more uncertainty distributions.

In some implementations, uncertainty distributions can include uncertainty from demand. For example, global markets can unexpectedly vary from time to time creating varying levels of demands for products. This varying level of demand can change purchase orders which are eventually shipped using one or more ships. In order to determine one or more routes for a ship or a shipping network, the system 200 or system 500 of system 500, among other systems described herein, can generate predictive routes for ships to deliver cargo in the future. If cargo is changed due to order changes, this can affect the route or shipping network—e.g., by decreasing a shipping weight, changing leg time for a trip, among others. One or more models trained to predict demand can be used, e.g., by the distribution engine 210, to predict demand. The demand can indicate demand for a particular type of good to be shipped as cargo on one or more shipping routes. One or more other models can determine a change in shipping parameters of interest given the uncertainty in demand—e.g., much less demand can lead to much less of a particular type of cargo being scheduled to ship, which can cause a system to determine that other cargo should be assigned to be shipped, e.g., or the ship will be light which can make it more susceptible to inclement weather.

In stage C, the ship interface 214 sends the route instructions 216 to the ship 202. The route instructions 216 can indicate the route determined by the route comparison engine 212 to be the current optimal route. The ship interface 214 can include one or more input/output devices of the control unit 204 for connecting with a computer of the ship 202.

In some implementations, the control unit 204 determines updates to a given route. For example, based on changing conditions, the control unit 204 can provide updates to the ship 202. If weather conditions at a first port are predicted by the control unit 204 to be poor or dangerous while the ship 202 is scheduled to be there, the control unit 204 can provide an updated route to the ship 202 indicating a new route that either changes a speed, increases a wait time along a portion of the route before the port, changes port, changes order of ports to be visited, among other corrections.

In some implementations, a sampling method is used to assess performance of a given network to stochastic events. For example, the control unit 204 can sample from distribution of port delays or weather scenarios and see an impact on fuel consumption and arrival times for one or more routes of the ship 202.

In some implementations, a sampling method is used to optimize or re-optimize network using robust optimization. For example, the control unit 204 can determine or select a cost function based on a probability distribution, e.g., fuel consumption at 95th percentile. Sampling can be used by the control unit 204 to penalize brittle networks that might have good mean performance but bad performance in off nominal cases, e.g., long trail of wait time distribution.

In some implementations, a sampling method, such as Monte Carlo, is used to generate an efficient frontier for multi-objective rather than a single point estimate. In some implementations, a sampling method is used to simulate counterfactual outcomes like potential zones of danger. As shown in FIG. 2, the control unit 204 generates distributions from a list of real world wait times. The control unit 204 can combine real world categorical distribution with different kinds of parametric distributions to simulate how to de-risk routes that are on average the same but have, e.g., different long tailed wait times.

FIG. 3 is a diagram showing an example of a generated distributions for wait times at a port. The raw wait time 302 of [35, 46, 27 . . . 45, 45] is converted to a distribution 304. The distribution 304 can be generated by the control unit 204 in the FIG. 2 and included in the distributions shown in item 208 to generate one or more simulated routes for comparison. Wait times can be in any suitable units, such as hours, days, weeks, minutes, among others.

One or more distributions, e.g., distributions 304 and 306, can be combined to generate a single distribution, e.g., distribution 308, representing a given feature of a route over the course of the route, e.g., wait times at ports over a period of a route. In some implementations, a port may not have statistics like average wait time. The control unit 204 can generate a parametric distribution, e.g., negative exponential, and combine two or more distributions in a route that goes from a first location, e.g., Savannah, to a second location, such as a new port that doesn't have statistics like average wait time using Monte Carlo, e.g., by sampling from one or more distributions including a distribution representing the first location or a distribution representing the second location.

In some implementations, the control unit 204 determines that two routes have a same average wait time, but one route has a longer tailed risk, e.g., distribution 208a has a greater likelihood of much longer wait times compared to distribution 208b or 208c. The control unit 204 can determine that, because the distribution 208a has a non-zero or above a threshold likelihood of a significant wait time, e.g., satisfying a threshold, the control unit 204 chooses another distribution representing another route to provide to the ship 202, e.g., the distribution 208b, or a combination of one or more distributions representing a route with one or more ports along it. In this way, the control unit 204 can take advantage of routes with similar average wait times but choose that one that has a lower risk, e.g., distribution 208e over distribution 208d.

In some implementations, the control unit 204 generates simulated and optimal routes without obtaining data from a ship. For example, the control unit 204 can generate routes between one or more ports or other locations. The control unit 204 can store simulated routes or optimal routes in memory. The control unit 204 can obtain requests for optimal routes, retrieve one or more optimal routes according to the data of the request from stored memory, and provide the one or more optimal routes to the requesting device. In this way, the control unit 204 can preemptively compute routes when compute resources are available, e.g., on a cloud processing system of the control unit 204. The control unit 204 and the ship 202 can communicate over one or more suitable networks. The control unit 204 can include one or more computers communicably connected to one another.

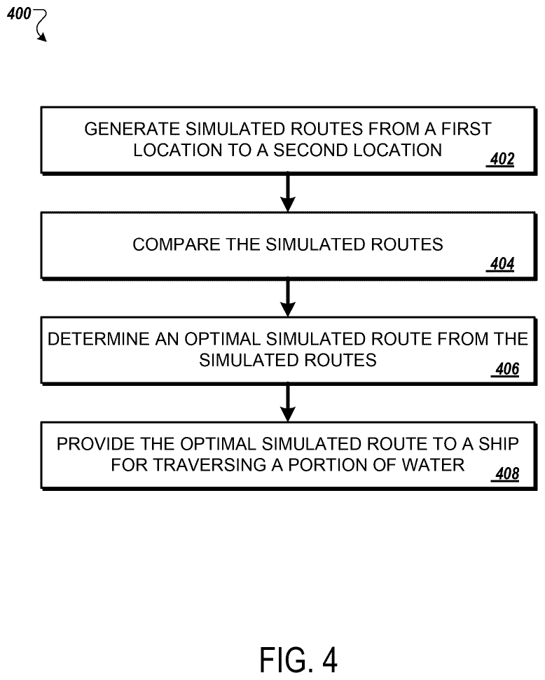

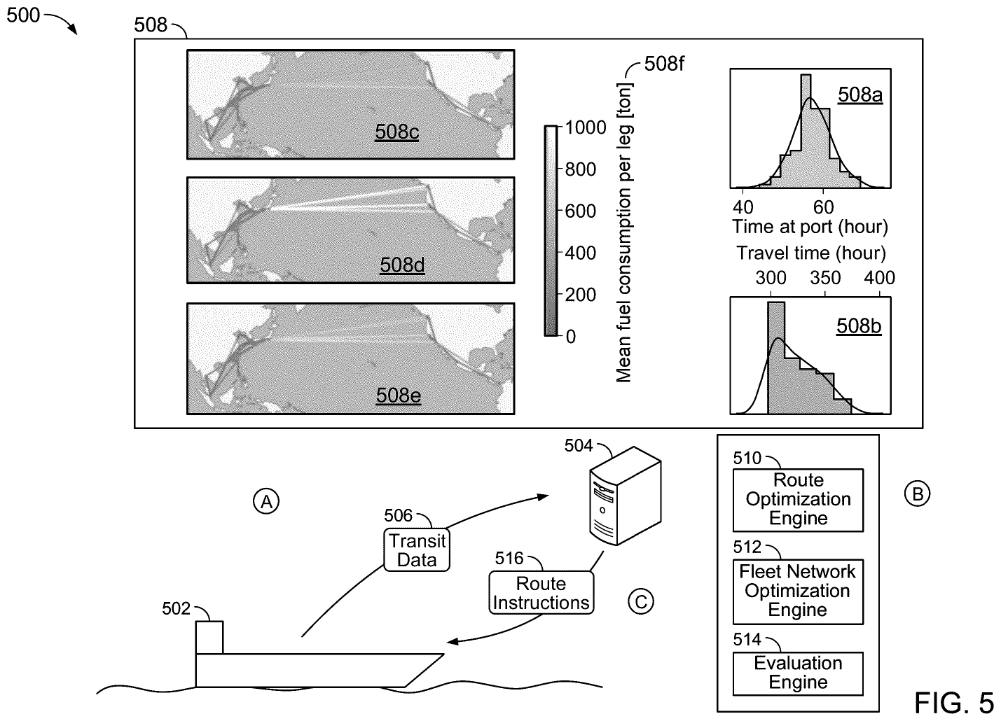

FIG. 4 is a flow diagram illustrating an example of a process 400 for ship network optimization. The process 400 may be performed by one or more electronic systems, for example, the system 200 of FIG. 2.

The process 400 includes generating simulated routes from a first location to a second location (402). For example, as shown in FIG. 2, the distribution engine 210 of the control unit 204 can generate simulated routes for the ship 202. The control unit 204 generate simulated routes using one or more generated distributions. Distributions can represent one or more features of a route, such as wait times, weather events, among others.

The process 400 includes comparing the simulated routes (404). For example, the route comparison engine 212 of the control unit 204 can compare one or more simulated routes for the ship 202 to determine an optimal route. The route comparison engine 212 can generate one or more parameters representing one or more distributions of a route and compare the one or more parameters of one route to one or more parameters of another route to determine an optimal route.

The process 400 includes determining an optimal simulated route from the simulated routes (406). For example, the route comparison engine 212 can compare one or more parameters of two or more routes. The route comparison engine 212 can compare one or more parameters to one or more thresholds. Based on one or more comparisons, the route comparison engine 212 can determine an optimal route.

The process 400 includes providing the optimal simulated route to a ship for traversing a portion of water (408). For example, the control unit 204, e.g., using the ship interface 214, can provide the route instructions 216 to the ship 202. The route instructions 216 can be configured to control the ship 202 or prepare the ship 202 for navigating on the route indicated by the route instructions 216.

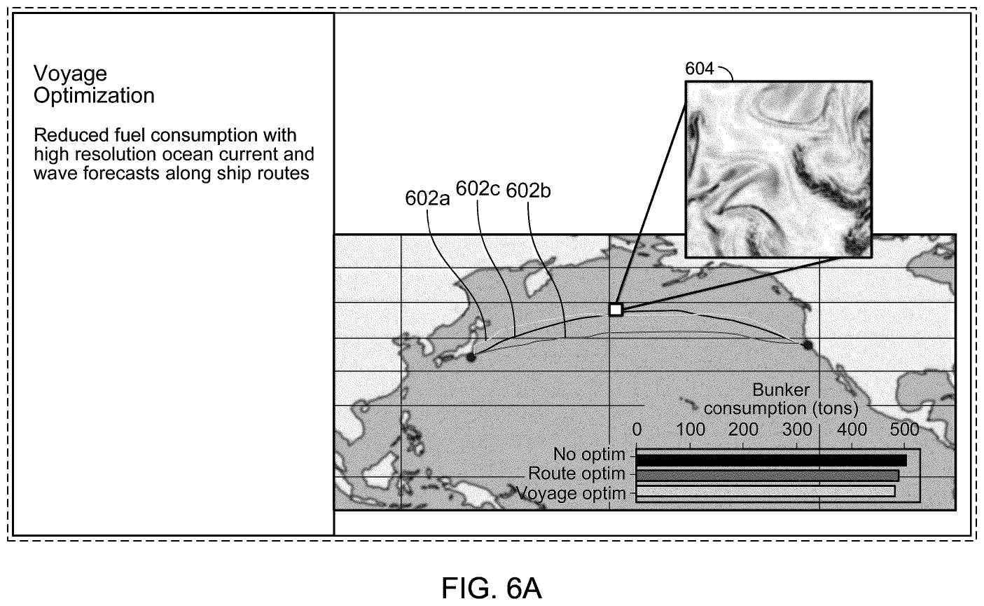

FIG. 5 is a diagram showing an example of a system 500 for ship network optimization. The system 500 includes a ship 502 and a control unit 504. The system 500 shows an example of the control unit 504 using simulations and generated distributions, e.g., for wait times at a port to determine one or more simulated routes and provide route instructions 516 to the ship 502.

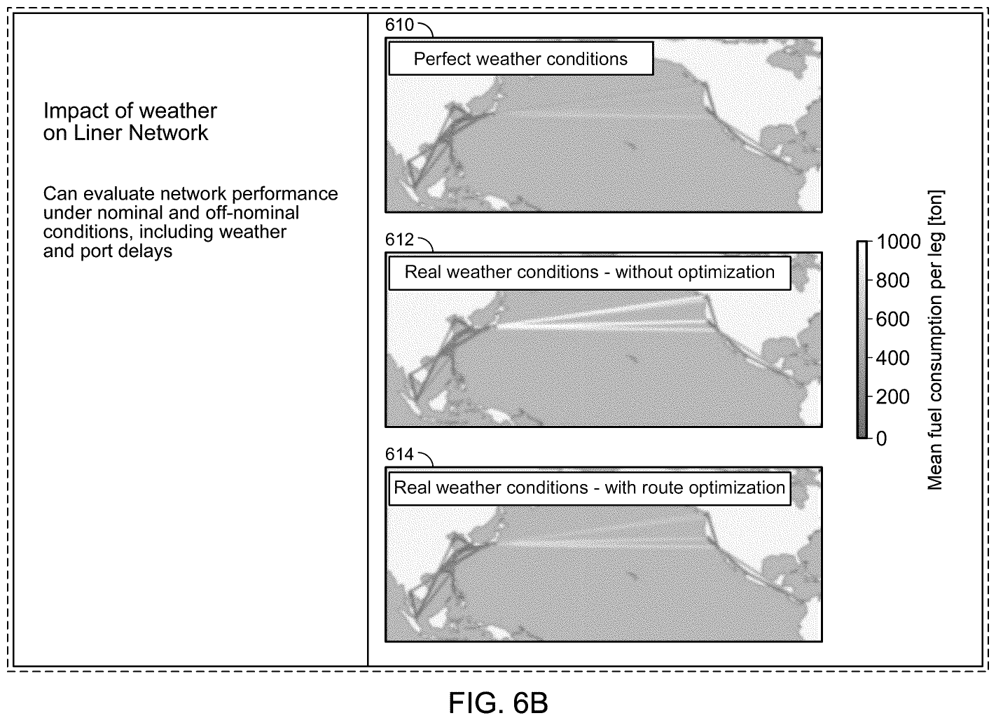

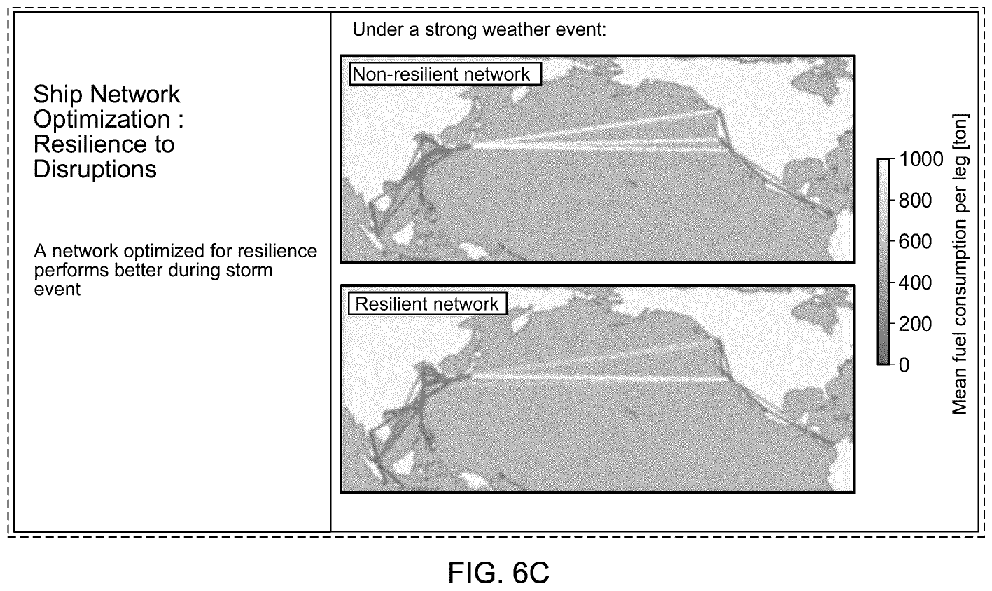

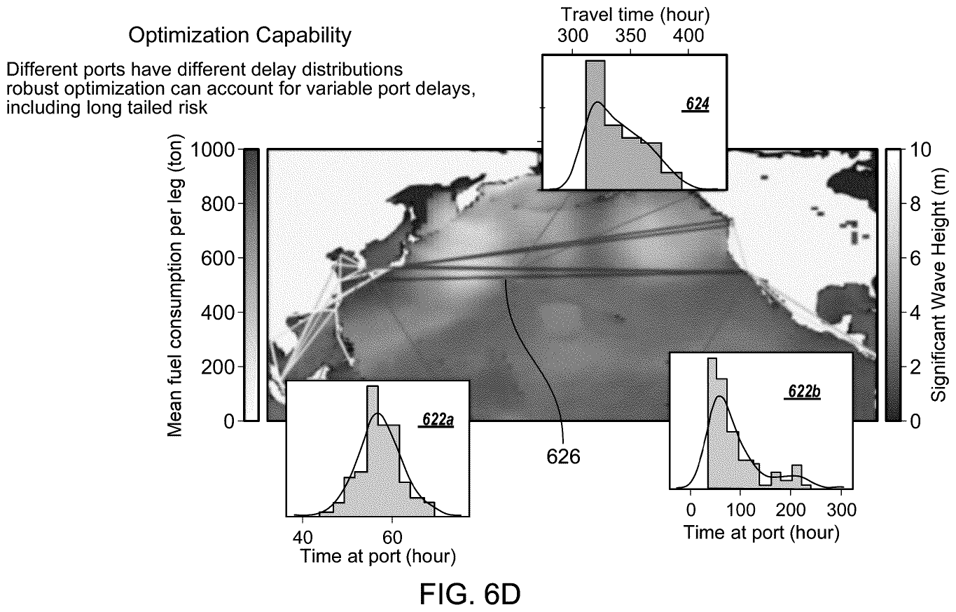

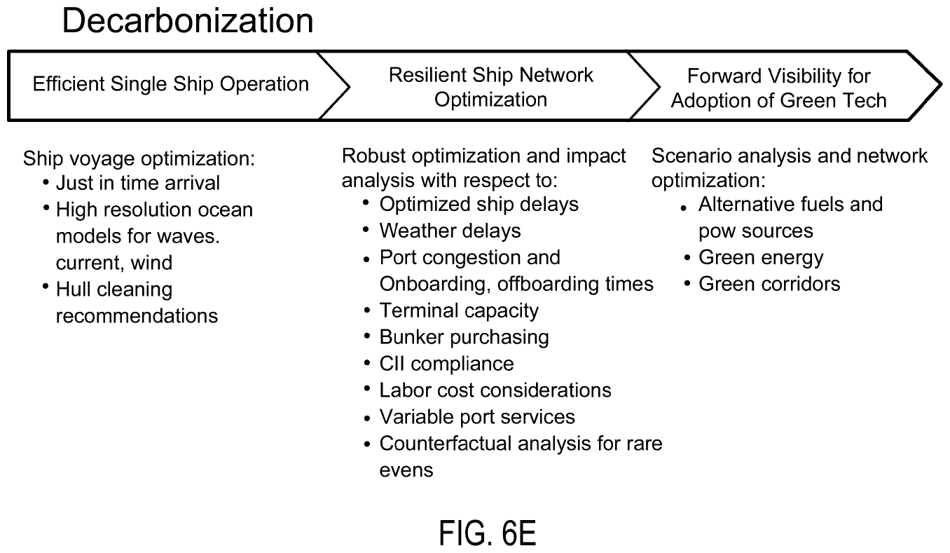

In stage A, the ship 502 provides transit data 506. The transit data can include an indication of a current location of the ship 502, a destination for the ship 502, preferred routes of the ship 502, route preferences, among others. The control unit 504 obtains the transit data 506. The control unit 504 generates one or more distributions shown in item 508 and shown in more detail in FIG. 6A-D. In some implementations, the control unit 504 obtains the transit data 506 from another computing device, e.g., a device that monitors one or more ships of a shipping fleet. In some implementations, the transit data 506 includes data of one or more ships of a shipping fleet.

In stage B, the route optimization engine 510 of the control unit 504 can be used to generate one or more of the simulations or distributions shown in item 508. The generated data can be used by the fleet network optimization engine 512 to determine what route is optimal for the ship 502 or other ships in a corresponding fleet. In some implementations, the route optimization engine 510 or the fleet network optimization engine 512 combines distributions. For example, the route optimization engine 510 can combine generated distribution 508a with another generated distribution for wait time at a port to determine a sum wait time for a voyage of the ship 502 or other ship of a corresponding shipping fleet.

In another example, the route optimization engine 510 can combine distributions of different types, such as distributions indicating a likelihood of travel time or distributions indicating a likelihood of wait time at ports or distributions indicating travel time, e.g., affected by weather, sea currents, among others. Change in a dynamic system such as the ocean, port traffic, among other features can be modeled using one or more modeling techniques or machine learning techniques.

The route optimization engine 510 can determine what route is optimal for the ship 502 using, e.g., preferences of the ship 502, standard preferences for reducing time or pollution, saving fuel, among others. In some implementations, the route optimization engine 510 determines an average wait time or other parameter based on one or more generated distributions to compare between one or more generated distributions.

In some implementations, the fleet network optimization engine 512 uses data obtained from the route optimization engine 510. For example, the fleet network optimization engine 512 can obtain optimized routes for one or more ships within a given fleet. The optimized routes can be generated by the route optimization engine 510 after the route optimization engine 510 generates one or more simulated routes, e.g., 508c-e and corresponding axis 508f indicating fuel consumption along each simulated route, and determines an optimal route from among the simulated routes. The optimal route can be the route that minimizes a given feature of a route or has a cumulative value that indicates multiple features of a route that satisfies a threshold. Features of a route can include fuel spent, time spent, among others. A cumulative value can include a weighted average of one or more values indicating features of a route.

In some implementations, the fleet network optimization engine 512 determines optimal routes for one or more ships of a fleet. For example, the fleet network optimization engine 512 can determine an optimized route for each ship of a fleet using the route optimization engine 510 for each ship.

In some implementations, the fleet network optimization engine 512 takes into account one or more features of a fleet, such as ship fleet size or its composition. In some implementations, the fleet network optimization engine 512 uses data indicating services or markets to serve. The fleet network optimization engine 512 can obtain data obtained by the control unit 504 from one or more sources. In a similar way, other engines of the control unit 504 can obtain corresponding data for processing.

In some implementations, the fleet network optimization engine 512 optimizes using one or more constraints. For example, the fleet network optimization engine 512 can use one or more of: ports capacities or services, bunker purchasing, CII compliance and other regulations, or labor cost considerations as constraints. The fleet network optimization engine 512 can provide a robust, resilient, ship fleet network that provides, at least, cargo routing, fleet deployment, or scheduling of a fleet, such as a fleet that includes the ship 502.

In some implementations, the evaluation engine 514 evaluates performance of one or more generated networks, such as a generated shipping network using data from one or more of the route optimization engine 510 or the fleet network optimization engine 512. For example, the evaluation engine 514 can analyze either a current or historical network and an optimized ship fleet network, e.g., a network that includes data from one or more of the route optimization engine 510 or the fleet network optimization engine 512. The evaluation engine 514 can evaluate whether a given network operates in a best way or not. The evaluation engine 514 can perform comparisons under nominal and off-nominal conditions, including weather delays, port congestion, and onboarding/offboarding times. The evaluation engine 514 can provide simulations that compare networks using counterfactual analysis that represent rare events, such as port or canal closures. In this way, the evaluation engine 514 can help ensure performance of a network over time.

The control unit 504 can provide data to a requesting device using data generated by at least one of the route optimization engine 510, the fleet network optimization engine 512, or the evaluation engine 514. A combination of these components can allow for planning future improvements and expansions using different scenario analysis. For example, a shipping network can be optimized, e.g., by the control unit 504, for the adoption of green fuel or reduced power use by considering which ports provide alternative green fuels, such as low carbon fuels, hydrogen, ammonia, methane, biofuels, and which routes are most amenable to alternative power. Furthermore, scenarios on how to adopt green fuel or reduced power use within the network without disrupting service can be provided, e.g., by the control unit 504 to a requesting device.

In stage C, the control unit 504 sends the route instructions 516 to the ship 502. The route instructions 516 can indicate the route determined by the route optimization engine 510 to be the current optimal route. The control unit 504 can include one or more input/output devices for connecting with a computer of the ship 502.

In some implementations, the control unit 504 determines updates to a given route. For example, based on changing conditions, the control unit 504 can provide updates to the ship 502. If weather conditions at a first port are predicted by the control unit 504 to be poor or dangerous while the ship 502 is scheduled to be there, the control unit 504 can provide an updated route to the ship 502 indicating a new route that either changes a speed, increases a wait time along a portion of the route before the port, among other corrections. Similar updates can be provided either by a provided network or by subsequent updates by the control unit 504 for one or more ships in a shipping fleet.

In some implementations, a sampling method is used to assess performance of a given network to stochastic events. For example, the control unit 504 can sample from distribution of port delays or weather scenarios and see impact on fuel consumption and arrival times for one or more routes of the ship 502.

In some implementations, a sampling method is used to optimize or re-optimize network using robust optimization. For example, the control unit 504 can determine or select a cost function based on a probability distribution, e.g., fuel consumption at 95th percentile. Sampling can be used by the control unit 504 to penalize brittle networks that might have good mean performance but bad performance in off nominal cases, e.g., long trail of wait time distribution.

In some implementations, the control unit 504 generates simulated and optimal routes without obtaining data from a ship. For example, the control unit 504 can generate routes between one or more ports or other locations. The control unit 504 can store simulated routes or optimal routes in memory. The control unit 504 can obtain requests for optimal routes for a ship or a fleet of ships, retrieve one or more optimal routes according to the data of the request from stored memory, and provide the one or more optimal routes or recommendations to the requesting device. In this way, the control unit 504 can preemptively compute routes or recommendations when compute resources are available, e.g., on a cloud processing system of the control unit 504. The control unit 504 and the ship 502 can communicate over one or more suitable networks. The control unit 504 can include one or more computers communicably connected to one another.

In general, techniques described herein can improve efficiency and resiliency of a single ship or a fleet of ships. In some implementations, techniques described herein use methods or operations for solving a vehicle-routing problem (VRP) and the multi-commodity flow (MCF) problem. A goal of the techniques described can include finding the best routes for a fleet of ships transporting goods across a network of ports, taking into account factors or route features including demands of those ports, capacity of the ships, and time the ships take to navigate between ports. Routes can then be subjected to various weather simulations which can be generated using one or more machine learning models.

Due to the complexity of the problem, it may be difficult to also add in factors such as weather and ocean conditions among other dynamic factors. These dynamic factors can have a large influence on ship travel times and energy consumption, e.g., compare image 610 and 612 in FIG. 6B. Techniques described herein solve the problem by performing such simulation in addition to determining other route features such as demands of ports, capacity of the ships, and time the ships take to navigate between ports.

FIG. 6A is a diagram showing an example of voyage optimization. In some implementations, the control unit 504 generates one or more simulated shipping routes. For example, the control unit 504 can generate simulated routes 602a-c. The control unit 504 can simulate route features, including ocean currents shown graphically in item 604. The control unit 504 can simulate the routes 602a-c and corresponding route features, such as ocean currents, to determine an optimal or near optimal route for a given ship, such as the ship 502. In some implementations, an optimal route is the route with the lowest fuel consumption and therefore the lowest emissions of greenhouse gases.

FIG. 6B is a diagram showing an example of an impact of weather on a network for shipping. Image 610 shows simulated routes for perfect or ideal weather conditions across the Pacific. Image 612 shows real weather conditions and how the real world weather conditions affect mean fuel consumption shown as a range from 0 to 5000. Image 612 shows how fuel consumption can increase along a route when real world weather simulation is performed along the route. The control unit 504 can perform such real-world weather simulation to determine one or more ship routes. Image 614 shows optimized routes, e.g., routes optimized by the control unit 504, taking into account the change in fuel consumption and the real-world weather effects that affect such consumption along a given route. In general, routes can be adjusted to maximize fuel efficiency or minimize transit time taking into account weather, current, or other route features.

FIG. 6C is a diagram showing an example of a ship network resilient to disruptions. In some implementations, the control unit 504 can generate a network that provides routes that avoid storm systems. For example, a storm system or other event can make some regions unpassable, dangerous, or liable to increase fuel consumption. The control unit 504 can identify those regions and determine optimal routes that avoid those regions.

FIG. 6D is a diagram showing an example of optimization of shipping networks. In some implementations, the control unit 504 generates one or more distributions. For example, the control unit 504 can generate a distribution for a port along a route indicating an amount of wait time that a ship will wait at the port if they pass through the port, e.g., items 622a-b. Other distributions can indicate travel time, e.g., item 624, weather events, among other route features. The control unit 504 can use one or more distributions to determine a total route. In some implementations, the control unit 504 combines one or more distributions to determine one or more distributions that describe a given route, e.g., route 626. The control unit 504 can compare one or more routes based on one or more distributions used to describe the given routes. In some implementations, the control unit 504 generates values that represent one or more distributions, such as a mean, average, maximum, among others. The control unit 504 can compare one or more generated values to one or more other generated values to compare one or more routes with one another.

FIG. 6E is a diagram showing an example of elements of decarbonization for shipping networks. In some implementations, the control unit 504 determines one or more recommendations or routes to reduce an amount of carbon released into the environment through the burning of fossil fuels, such as the fuels used to power shipping vessels. Other recommendations can include hull cleaning or other ship maintenance. The techniques described herein, including those discussed with reference to FIG. 5 and the system 500 can enable just in time arrival for shipping. The control unit 504 can generate detailed resolutions for modeling ocean currents and other effects to determine whether one route is more optimal compared to another.

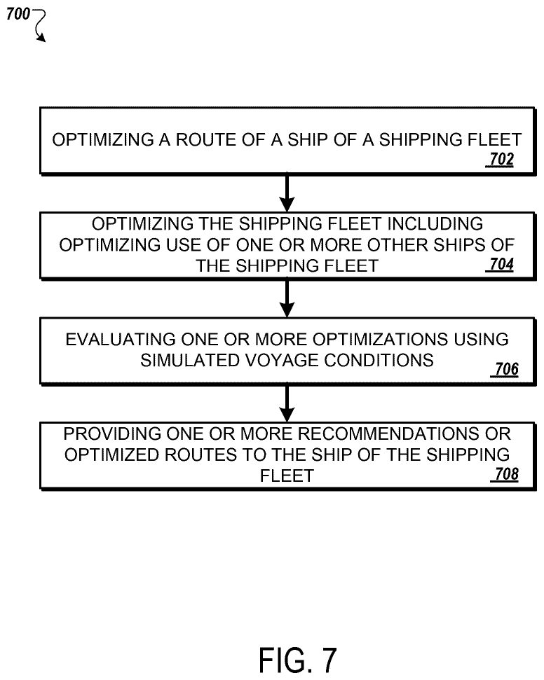

FIG. 7 is a flow diagram illustrating an example of a process 700 for ship network optimization. The process 700 may be performed by one or more electronic systems, for example, the system 500 of FIG. 5.

The process 700 includes optimizing a route of a ship of a shipping fleet (702). For example, as shown in FIG. 5, the control unit 504 using the route optimization engine 510 can optimize a route of the ship 502. Route optimization can include generating one or more simulated routes, as shown in images 508c-e. Each route can have different features including fuel usage, travel time, risk level, among others. The route optimization engine 510 can compare one or more simulated routes and determine a given optimal route. In some implementations, the route optimization engine 510 uses a cost function to determine which route costs the most or least as the optimal route. A given function can account for constraints or preferences obtained by the control unit 504 for a given ship or a fleet of ships.

The process 700 includes optimizing the shipping fleet including optimizing use of one or more other ships of the shipping fleet (704). For example, the fleet network optimization engine 512 can obtain one or more optimal routes from the route optimization engine 510. The fleet network optimization engine 512 can determine one or more recommendations or optimal routes for one or more ships. In some implementations, the fleet network optimization engine 512 determines other actions. For example, the fleet network optimization engine 512 can determine what cargo to store for what routes, departure time, route locations, speed along route, among others.

The process 700 includes evaluating one or more optimizations using simulated voyage conditions (706). For example, the evaluation engine 514 can determine one or more evaluations based on output of one or more of the fleet network optimization engine 512 or the route optimization engine 510. The evaluation engine 514 can analyze either current or historical data and optimize a ship fleet or single ship. The evaluation engine 514 can evaluate whether a given network, including simulations generated by one or more of the fleet network optimization engine 512 or the route optimization engine 510, operates in an optimal way or not. The evaluation can be performed under nominal and off-nominal conditions, including weather delays, port congestion, and onboarding/offboarding times. This allows for counterfactual analysis for rare events such as port or canal closures.

The process 700 includes providing one or more recommendations or optimized routes to the ship of the shipping fleet (708). For example, the control unit 504 can provide data to one or more requesting devices. The control unit 504 can provide data indicating route instructions 516 to the ship 502 or a computer associated with the ship 502, such as a computer onboard or otherwise communicably connected to the ship 502. In some implementations, the computer onboard the ship 502 controls the ship 502. The control unit 504 can provide instructions that, when executed by one or more computer elements on the ship 502, control operations of the ship 502, including a route, speed, fuel consumption, rudder, propellers, among others.

In some implementations, techniques include solving one or more problems, such as designing efficient and resilient services for maritime shipping or passenger vessels. In general, techniques described in this document can include determining which vessels should visit which ports in what order and with what cargo. There are many possible configurations for these networks, including hub and spoke, butterfly, among other arrangements. The design of these networks can account for a number of considerations such as contractual obligations, port service availability, bunker pricing, port loading and unloading times, labor costs, terminal capacity, carbon footprint, or fuel consumption.

Designing high performance networks to meet these constraints can be an exceptionally difficult challenge. Designing for nominal conditions alone can lead to brittle service networks that are susceptible to external disruption such as port delays and storms. One challenge is designing a resilient network that performs well under both nominal and off-nominal conditions.

Techniques described can include systems that combine ocean modeling, artificial intelligence, and optimization with advanced data infrastructure and information security. Techniques can include optimization systems that build on top of data infrastructure and security platforms to obtain and process data for one or more shipping optimizations. Techniques described in this document can provide resilient and efficient network optimization that can be customized using real world constraints. By incorporating effects of weather events, variable port delays, fluctuating demand, among other factors, it is possible to reduce the need for costly remediations and respond more efficiently and timely to emergent disruptions.

In some implementations, techniques described extend beyond ship route optimization. Whereas route optimization focuses on a single vessel navigating between two specified ports, ship network optimization can include optimization of an entire fleet accounting for effects from a single delayed vessel or closed port and determining how such effects propagate through a shipping network.

In some implementations, systems for route or network optimization combine optimization with high resolution ocean modeling. Systems can provide resiliency, agility, flexibility, and sustainability. Using average port wait times and average crossing times for optimization can result in poor performance when disruptions occur, leading to environmentally impactful and costly scenarios—e.g., expending additional fuel on an inefficient route path, using more vessels than are required to transport cargo to one or more destinations, missing a contractual obligation, chartering an extra vessel, modifying the port rotation, or portaging cargo to a nearby port.

Instead of using average port wait times and average crossing times, systems described in this document can provide robust optimization by leveraging high resolution ocean weather models and data on port delays and other potential disruptions to not only reduce the frequency of such costly disruptions but also provide improved agility in analyzing the optimal response when such events do occur.

FIG. 6D shows a set of services connecting ports in the North Pacific region on a benchmark test case. Each leg of the service has a variable cost based on a distribution of historical weather events. Similarly, each port has a variable associated delay. A Tidal network optimized to be resilient to such variable events reduced fuel consumption by 64% during a severe storm event compared to a network optimized solely for operation under nominal conditions.

In general, techniques described in this document include using ocean modeling and numerical optimization to provide significant advances in resiliency and performance for liner networks on industry standard benchmark datasets.

In some implementations, systems are configured to determine actions for one or more vessels in response to changing environmental conditions. Actions can include operational decisions to adjust to changing conditions, one-off requests, and unexpected disruptions. For example, a single vessel may be delayed, and systems described in this document can evaluate and determine whether to swap in a different vessel, change port rotation, or have a delayed delivery. Such evaluations can use one or more of ocean simulations, route optimization, or network optimization to determine a set of one or more recourses to be provided to a user for a final decision or to enact autonomously by configuring and sending a signal to one or more vessels. As used herein, vessels can refer to ships and vice versa. In general, recourse decisions can have ripple effects through a shipping network which can be modeled by systems described.

Systems can obtain data indicating contractual obligations, customer relationships, charter fees (e.g., for an extra vessel), port constraints, vessel specifications, cargo restrictions, and propagation of any changes through a network. Systems can process such data, including additional data or a subset of this data, to evaluate recourse options systematically and optimize for profit or other quantities of interest.

This document describes techniques that enable systematic evaluation and optimization for, e.g., reducing emissions, reducing fuel consumption, increasing profit or other quantities of interest. In some implementations, techniques include systems that include one or more of a candidate generation engine, a propagation engine, and a ranking and selection tool.

In some implementations, techniques include using Agent-Based Modeling (AMB). For example, systems implementing techniques described herein can represent one or more ships as agents that interact with one another in a shipping environment. Other computational modeling techniques can be used in some cases. In some implementations, techniques include using Mixed Integer Programming (MIP). For example, systems implementing techniques described herein can use MIP to help find optimal solutions for multiple potential solutions—e.g., multiple future shipping networks in response to one or more disruptions. MIP can be used to approximate a solution using integers. Subsequent processes can be used to determine an optimal solution, or a solution provided by MIP can be represented as the optimal solution, depending on implementation. In some implementations, techniques include using heuristics. For example, systems implementing techniques described herein can use heuristics to find approximate solutions to a problem of what changes to make to a shipping network, e.g., after one or more detected disruptions. Heuristics can include, e.g., using Port B when Port A is detected to be closed—e.g., based on port data or data provided by a user. Heuristics can be combined with other techniques, e.g., MIP, to help improve solution efficiency.

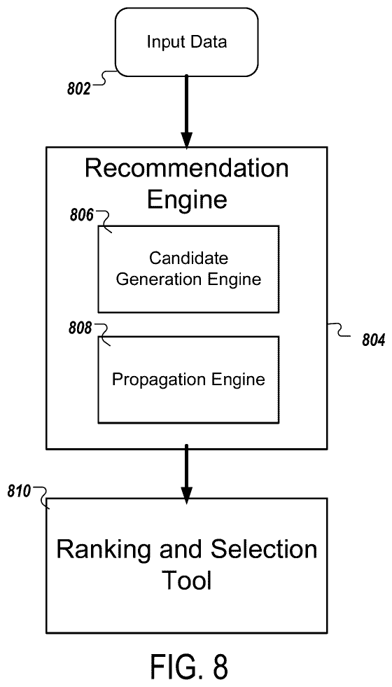

FIG. 8 is a diagram showing a system for selecting optimal shipping routes in a shipping network, e.g., after one or more disruptions are identified. As shown in FIG. 8, a candidate generation engine 806 can crawl through a space of potential modifications to a shipping network to find potential or promising candidate recourse suggestions. The candidate generation engine 806 can obtain input data 802. The input data 802 can include one or more of the following: cargo specifications, demand and contractual obligations, fleet vessel specifications, current fleet status, service specifications, port delay information, ocean weather forecasts, among others.

For the purposes of this document, “candidate recourse” and “candidate network” can both refer to a temporary change in the service network configuration to accommodate emergent conditions.

Potential modifications can include changing vessel allocation to add a new vessel into service or move a vessel from one service to another service. Modifications can also include changing which cargo is going on which vessel. Modifications can also include changing port rotation so that a given port is skipped, replaced by another port, or the order of port visits is changed.

A candidate generation engine 806 can use random sampling, simulated annealing, or genetic or evolutionary algorithms to sample from potential modifications. A candidate generation engine 806 can use a heuristic approach to sample from potential modifications, such as “in a port closure scenario, generate alternative routes through the N closest ports which allow transfer of goods between them and the closed port.” A candidate generation engine 806 can keep some parts of a network configuration fixed while varying other components either based on a fitness heuristic or random sampling.

A propagation engine 808 can evaluate a predicted fitness of one or more candidate networks and of a current network configuration. These fitness evaluations can be done using expected values or by using Monte Carlo sampling e.g., to propagate a full distribution. Propagation can be done over a single, partial day, or multi-day period. Propagation can incorporate information such as weather and wave forecasts, projected port delays, bunker costs, or other operational considerations. These data can be incorporated using heuristics, independent probability distribution functions, or joint probability distribution functions.

In some cases, a propagation engine 808 feeds into an optimization engine—e.g., included in the optimization engine—to provide a next iteration of candidate networks, e.g., based on the evaluated fitness of a prior iterations' candidates. An optimization iteration loop can repeat until candidate performance reaches a given threshold or converges. For example, in simulated annealing, a propagation engine 808 can be used to evaluate a fitness of a given batch of candidates and that fitness can inform the probability with which those candidates would be used as the new “seeds” with which to generate candidates in the candidate generation engine 806. In some cases, a user can input their own suggestion for a candidate network and the propagation engine 808 can be used to evaluate its predicted fitness.

A combination of the candidate generation engine 806 and the propagation engine 808 can be referred to as a recommendation engine 804 since the candidate generation and propagation engine can surface candidate networks and their expected performance over time (see e.g., recommendation engine 804 of FIG. 8). The recommendation engine 804 can take as input data a current network configuration, a current fleet status (e.g., which vessels are on time versus delayed), historical port delay data, contractual obligations, cargo information, customer priority, vessel specifications for all or some of the vessels in a fleet, and demand information, among others.

A recommendation engine 804 can also take as input weather data and weather forecasts. Forecasts can be generated by a regional ocean model or atmospheric model. Forecasts can include wind, wave height, precipitation, ocean currents, and temperature, among others. Estimated vessel transit times can be modified based on ocean weather forecasts and ship voyage optimization.

In some implementations, a ranking and selection tool 810 ranks candidate networks suggested by the recommendation engine 804 and evaluated by the propagation engine 808. Ranking can be done using a single metric, such as overall profit among others, or can be evaluated using multiple metrics, such as profit, greenhouse gas emissions, fuel consumption, number of changes required from original service, potential risk to customer relationships, among others.

The ranking and selection tool 810 can generate rankings using an expected value or risk. For example, the ranking and selection tool 810 can generate rankings for networks using expected profit (e.g., a mean value of the profit distribution from a propagation engine), or based on some other statistic such as the 90th percentile value from a profit distribution. Ranked recommendations can be presented to a user who can select a preferred option for a shipping service network. A system implementing a process shown in FIG. 8 can automatically generate and send one or more signals to one or more vessels after ranking or selecting one or more recourses corresponding to one or more optimized networks for shipping.

In some implementations, recommendations include automatic actions that are automatically executed if ranked in a top number of recommendations. For example, if a recommendation is the top ranked recommendation and does not include, or does include one or more predetermined actions (e.g., to prevent unwanted or approve wanted automatic actions), the actions can be automatically executed without user approval—e.g., users can approve ahead of a ranking or determination to one or more recommendations that include one or more actions. Actions can include transmitting one or more signals to other systems—e.g., to reroute ships, change ship speeds, activate new ships, among others.

A given use case can have multiple sort criteria. For example, a user can care about both profit and fuel consumption and rankings can be based on values corresponding to both profit and fuel consumption or another combination of parameters. Rankings can also be provided as a collection of plots, such as 3D or 2D plots, of different rankings such that an analyst can visually look at an efficient frontier and pick tradeoffs, e.g., fuel versus profit. A system, as described herein, can also provide a parallel coordinate plot with various options for candidate network modifications shown with respect to performance on different metrics.

Various candidate network modifications can be shown. Each can be optimized with respect to a different combination or weighting of the quantities of interest. A system can provide modifications or one or more candidate network visualizations to a user interface.

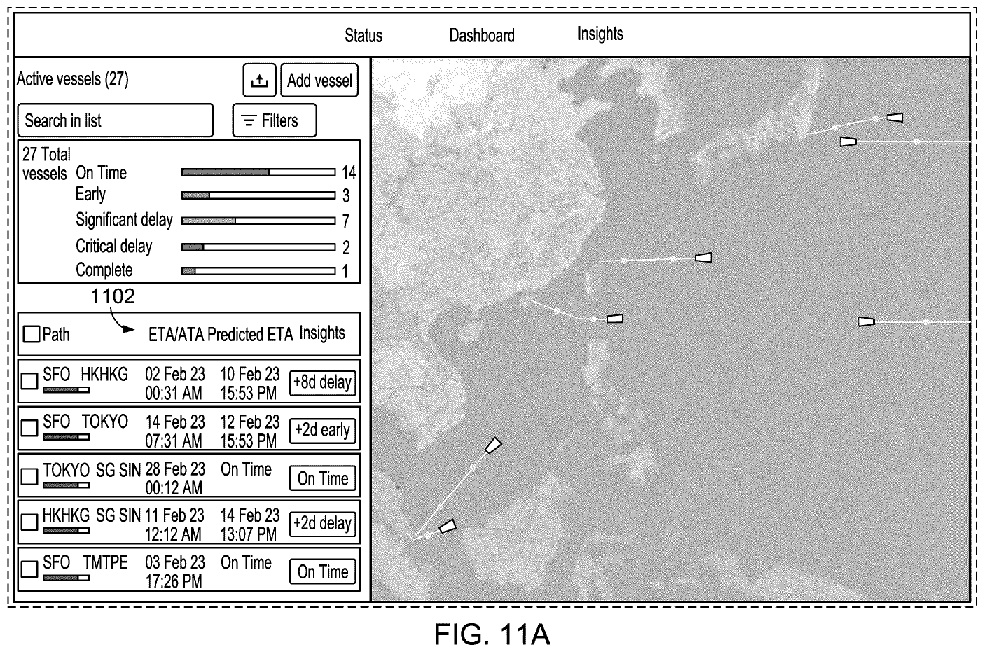

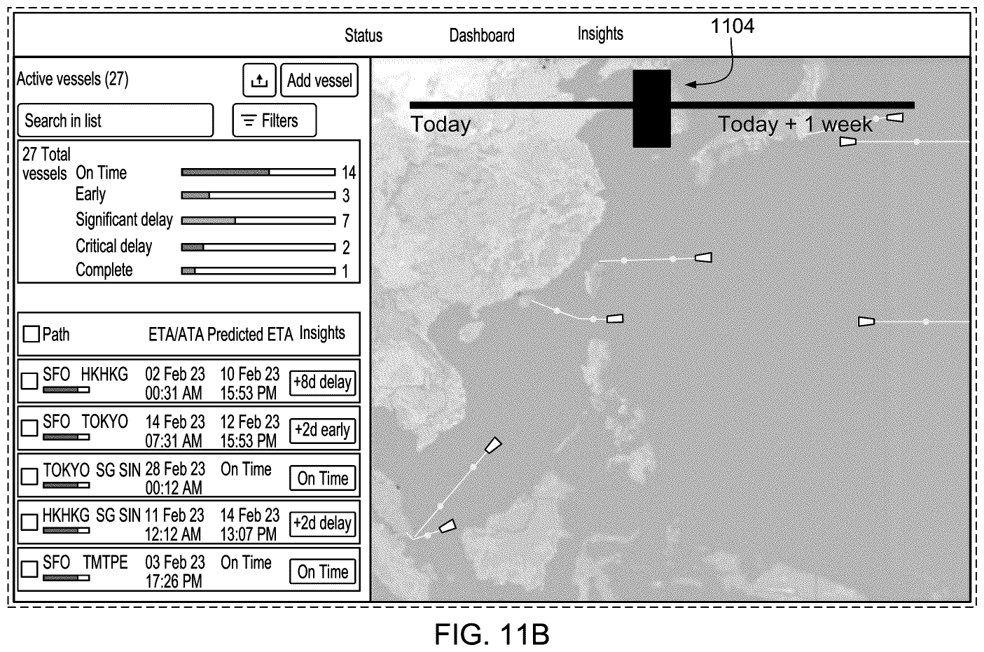

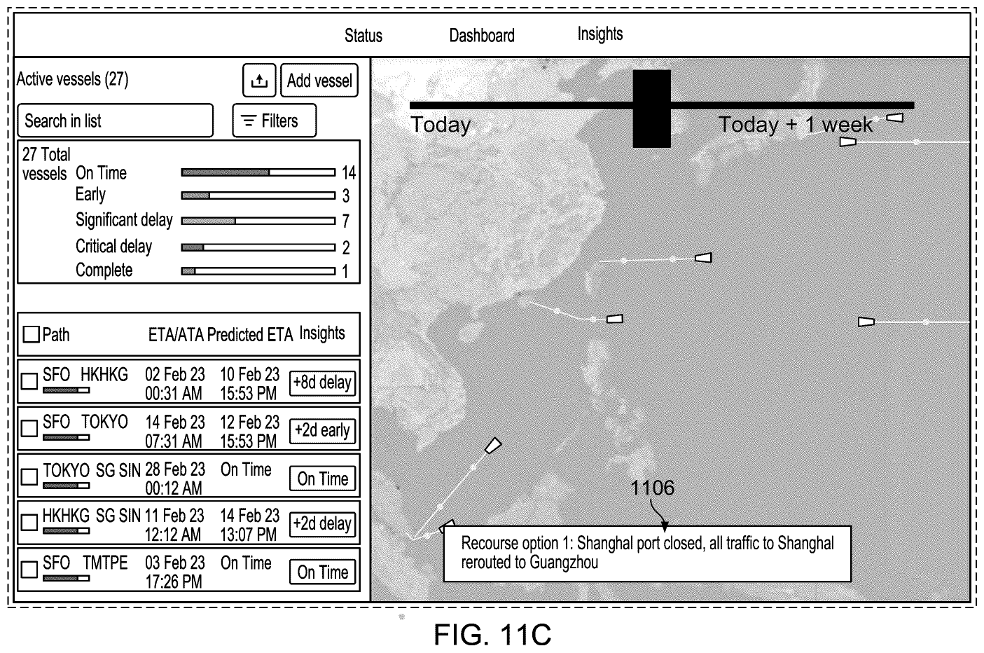

One sample workflow can include:
1. A system can provide a current status view of a fleet on a map. Map elements can include ship current locations, intended destination terminal, or on time or delayed status based on estimated arrival time and planned arrival time (see FIG. 11A-C). Determination of an estimated arrival time (e.g., item 1102 of FIG. 11A) can use a voyage optimization algorithm or historical data. A status can also include performance metrics such as expected profit, fuel consumption, number of delayed vessels, among others. User interface elements can include graphical interfaces similar to those shown in FIG. 11A-C.
2. A system can provide an application view for viewing forecasted fleet position at future times. This forecast could show expected status, or a full probabilistic analysis of status. The application view can be configured by the system with a user interface element, such as interface 1104 of FIG. 11B, to control both viewing predicted future positions and historical positions. Corresponding analysis and data for the predicted future positions and historical positions can be calculated and included in such an application view by a system as described herein.
3. A system can provide recourse suggestions, along with performance against various quantities of interest. Recourse suggestions can be based on one or more different objective functions. Performance of these suggestions against quantities of interest can be visualized and compared using one or more plots, e.g., a 2D or 3D pareto frontier plots, radar plots, or parallel coordinate plots. Plots can help visualize value generation and comparison performed by one or more systems described in this document to generate a recommended action—e.g., recommended recourse, berth allocation, tramp schedule, among others.

In some implementations, recourse recommendations are generated by one or more trained models. For example, a model can be trained using user feedback or based on historical data indicating recourses. For example, historical data can indicate that a certain user—e.g., shipping company-routes ships destined for Port XYZ to Port ABC when Port XYZ shuts down for a period of time that satisfies a threshold amount of time. Other amounts of time can correspond to other recourses. A model can be trained to learn the rerouting of ships in response to the particular port closure and ports similar to Port XY, such as nearby ports, ships carrying similar cargo to similar ports but not necessarily in the same area, among others.

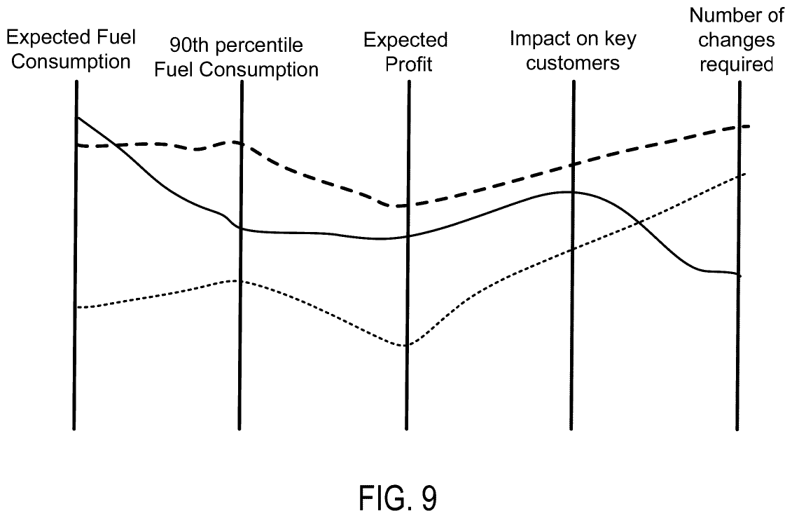

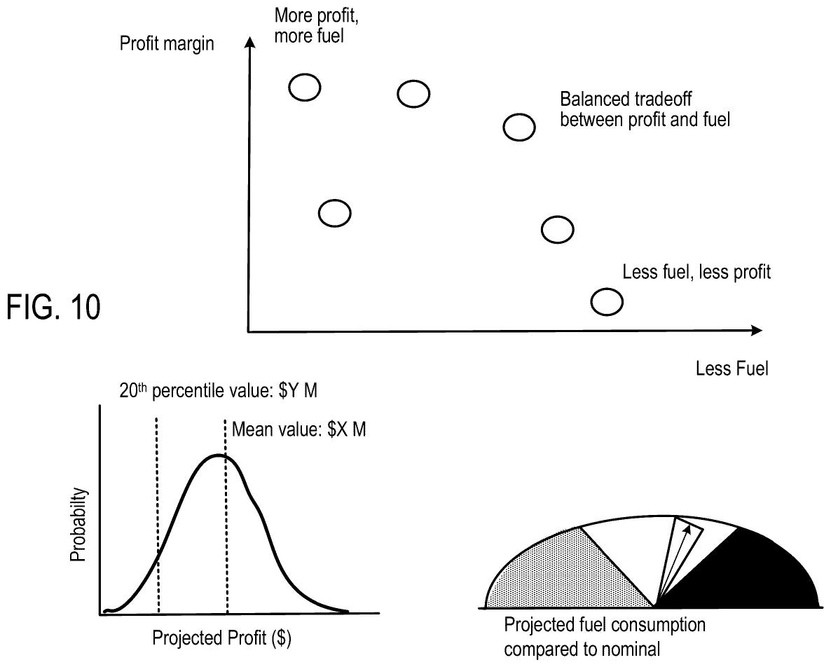

One example plot is shown in FIG. 9 which shows multiple lines corresponding to different recourse options. Different objective functions (e.g., different weights for different quantities of interest) can be used to generate lines shown in FIG. 9. Other representations of costs compared to benefit representations for shipping optimizations are shown in FIG. 10. For different objective functions, different recourse options can be preferable to other recourse options. A system can select the highest average function, lowest average function, or other value based on user preferences. Actions for a given recourse can be approved by a user or automatically executed, e.g., depending on a type of action, whether one or more actions have been previously approved, among other factors.
4. The forecast for any given recourse suggestion can be inspected in detail. For example, as shown in FIG. 11C, item 1106 indicates a particular recourse when the Shanghai port is closed. In this case, the system displays a potential candidate recourse option that would include routing traffic to Guangzhou. The system can automatically execute the recourse option by transmitting one or more signals or can present the option to a user using a display with an interface for accepting user input. The system can accept user input indicating approval of the recourse option and, in response, transmit one or more signals to control one or more ships to reroute or otherwise adjust course or action.
5. A candidate network option can be selected, and the system's forecasts will be updated to reflect the selection. For example, a system can use a propagation engine, such as the propagation engine 808, to forecast future shipping network conditions based on a given candidate network option being performed by the system and communicably connected shipping components, e.g., ships, ports, among others.

In some implementations, a system uses a form of berth allocation optimization. For example, a system can determine which berths to allocate to which vessels so that vessels can be loaded and unloaded efficiently while minimizing congestion using one or more machine learning models.

Traditionally, ports determine which berths to allocate to which vessels so that vessels can be loaded and unloaded efficiently while minimizing congestion. While many vessels operate on a liner schedule, and the associated terminals can create schedules for berths in advance, delays in maritime shipping are pervasive, requiring reallocation of berths. Other vessels operate on a “tramp” service, without a fixed schedule. In these cases, the associated terminals must allocate berths without a set schedule. When allocating berths, terminals must consider many factors including: size of vessel, allowable draught in berth, availability of tug boats or pilots, bunker needs, estimated vessel time of arrival at port, weather, storage availability, land side transport, customer relationships, and transportation from the berth to storage.

In some implementations, a system uses ocean weather models and probabilistic modeling to provide berth allocation optimization. The system can take into account uncertainty on predictions of weather, vessel ETAs, or unloading/loading times to provide recommended berth allocations/reallocations. Such berth allocation or reallocation can be included in a system, as described, for optimizing one or more shipping networks.

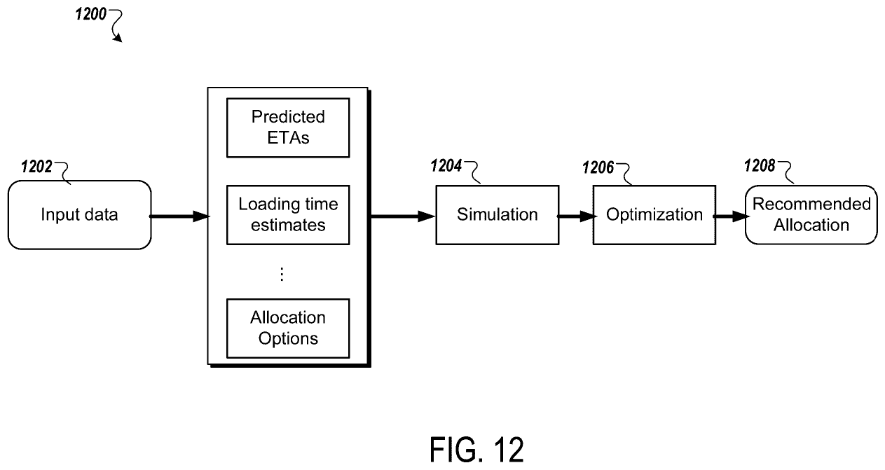

A system for berth allocation or reallocation can provide a multi-objective evaluation of the performance of those allocations. The system can model a “ripple effect” of allocations by simulating how congestion could vary over time for a given berth allocation. An agent-based model can be used to model vessels in route with cargo, vessels waiting at port, or vessels actively loading/unloading. A Monte Carlo based approach can be used to simulate the distribution of potential outcomes, where outcomes could include quantities of interest such as average port call time, number of vessels idling, total emissions from vessels at port, or number of delayed vessels over time. An example workflow 1200 is shown graphically in FIG. 12.

In some implementations, allocation recommendations are generated by one or more trained models. For example, a model can be trained using user feedback or based on historical data indicating allocations. For example, historical data can indicate that particular vessels are assigned to certain berths. Vessels can have particular cargo or particular arrival time criteria, among others. After a decision, the model can be updated using user feedback to adjust a recommendation provided or automatic action taken.

The workflow 1200 includes providing input data 1202 to one or more processing systems described in this document. For example, the input data 1202 can be provided to one or more systems configured to simulate ocean weather and routes of ships to determine an ETA of a vessel. The input data 1202 can be provided to one or more systems configured to obtain historical port wait times and predict wait times e.g., for particular vessels or during particular times trained using historical wait times corresponding to particular ships, among other features.

The input data 1202 can include one or more of high-resolution ocean weather models, port data, vessel data, cargo data, among others. Allocating berths for vessels can be included in one or more route or vessel optimizations. Optimization of berth allocation can help reduce shipping congestion and emissions.

Initial determinations e.g., for a particular set of one or more ships—can be propagated throughout a network. As shown in workflow 1200, simulation 1204 determines a ripple effect. For example, the simulation 1204 can use one or more ocean simulation models to determine an effect of a particular vessels journey on another vessel. A vessel can be delayed at Port XYZ causing a subsequent vessel to be delayed at the same port. A vessel can be impacted by weather causing a reroute that obviates another vessel's journey e.g., a first vessel can take at least some cargo of another vessel after a reroute to avoid a predicted weather event, port closure, vessel failure, among other events.

Workflow 1200 can include optimization 1206. For example, as discussed in this document, optimization can include optimization of routes or networks. A system implementing the workflow 1200 can determine one or more candidate routes or vessels for one or more routes as a first candidate network. Optimization 1206 can include comparing one or more candidate networks to minimize a cost function or determine a lowest value of a weighted summation, e.g., weighting factors such as fuel cost, environmental impact, cargo spoilage, total delivery time, among others. Specific cost functions can be used to determine a best network configuration, where a given network configuration can include a determination of one or more vessels to traverse one or more routes between two or more destinations.

The workflow can include generating a recommended allocation 1208. The recommended allocation 1208 can assign a given vessel to given berth. Berth assignments can be included in a network for shipping—e.g., included in a network of ships assigned to routes for traversing between two or more ports.

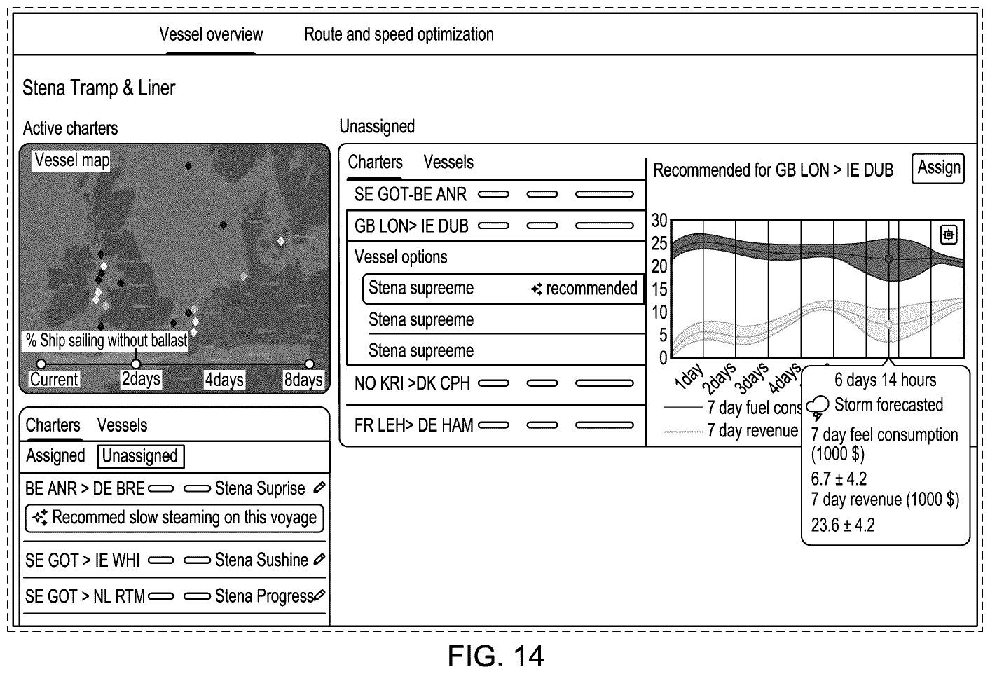

An example user interface generated and provided by a system as described in this document, e.g., shown in FIG. 11A-C and FIG. 14. A user interface for berth allocation can include a time bar interface. The time bar interface can allow selecting current, past, or future points, or ranges, of time. The system can update the data in the user interface in response to a user interacting with the time bar. For example, the system can predict future conditions at one or more berths in response to the user selecting a future time. The system can generate predictions and store data corresponding to those predictions such that, when a user selects a future time, the previously generated predictions can be shown with less response delay compared to generating after user input.

A system can generate a user interface that includes one or more of: vessel assignments—e.g., visual elements with vessel name and berth assignment, color coded based on status, such as red if delayed or green if nominal; unassigned vessels—e.g., visual elements representing vessel status, such as color coded elements that show white if a vessel is in port, gray if in route, or notification elements if ships are expected to be delayed in arrival; a map of port—e.g., rectangles can demarcate different terminals, dots can demarcate different berths, color coding can be used to show, for example, red dots for occupied berths, yellow for assigned berths, or green for unassigned berths; recommended re-assignments e.g., visual elements indicating which vessels are assigned to which berths; predicted performance metrics—e.g., 2D or 3D plots of average call time for current assignments, average call time for recommended allocation. Predicted performance metrics can include an uncertainty envelope indicating a measure of uncertainty calculated by a system for a given prediction.

An example process, e.g., performed by a system as described in this document, for providing berth allocation optimization can include one or more of: 8. obtaining input data to run high resolution ocean weather simulations; 9. obtaining input data on current berth allocations, in route vessel locations, cargo characteristics, vessel characteristics, among other shipping network data; 10. displaying current berth allocation data, including indicators of congestion such as delayed vessels and number of vessels idling; 11. providing options for recommended berth reassignments, along with predicted performance (e.g., with uncertainty for multiple quantities of interest. Quantities of interest can be integrated over time or may be shown as time varying quantities); 12. providing an interface configure to accept a user selection of a recommended reassignment.

While some vessels operate on liner schedules—with vessels assigned to fixed services with a set schedule and port rotation—other vessels operate on a tramp service where charters can be negotiated as time charters (e.g., carry 8 cargoes between terminal A and terminal B during a given 12 month period) or can be determined as spot contracts on an ad hoc basis. For fleets operating on a tramp service, a key challenge is the scheduling of vessels: which spot contracts to accept, which vessels should carry which cargoes, and what should be the port calls. Inefficient vessel scheduling can result in increased fuel consumption and corresponding emissions and lost profit.

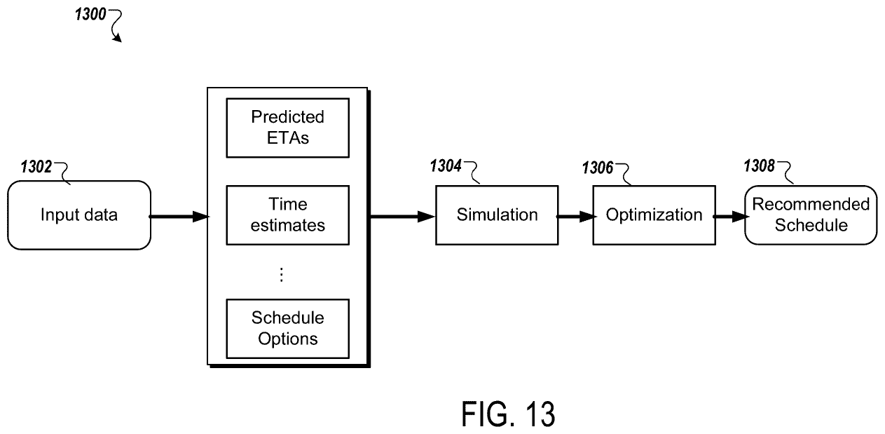

In some implementations, systems described in this document use tramp shipping vessel scheduling optimization. For example, systems can perform robust vessel scheduling for fleets of vessels operating on a tramp service (e.g., vessels not on liner schedules or not assigned fixed services with set schedule and port rotation). An example workflow is shown in FIG. 13.

The workflow 1300 includes providing input data 1302 to one or more processing systems described in this document. For example, the input data 1302 can be provided to one or more systems configured to simulate ocean weather and routes of ships to determine an ETA of a vessel. ETA of a vessel can include a determination of speed, route optimization, fuel consumption, among others.

The input data 1302 can be provided to one or more systems configured to obtain historical port wait times and predict wait times e.g., for particular vessels or during particular times trained using historical wait times corresponding to particular ships, among other features.

The input data 1302 can include one or more of high-resolution ocean weather models, port data, vessel data, cargo data, among others. Allocating tramp shipping vessels for shipping jobs can be included in one or more route or vessel optimizations. Optimization can help reduce shipping costs and emissions.

In some implementations, tramp shipping vessel schedules are generated by one or more trained models. For example, a model can be trained using user feedback or based on historical data indicating schedules. For example, historical data can indicate that particular vessels are scheduled for particular routes or for particular cargo. Vessels can be quipped for particular weather or not equipped for particular weather. A model can be trained to determine which vessels satisfy one or more criteria for being scheduled for a given shipping task or job.

In some implementations, systems for tramp shipping vessel scheduling optimization obtain input data for processing. For example, a system can obtain data to run one or more ocean weather simulations. An ocean weather simulation can predict wave heights and ocean currents, among other ocean weather. A system can obtain data, e.g.: on port call times, demand data (e.g., which charters contracts are currently active, which spot contracts are available or predicted to become available, among others), or fleet data (e.g., current vessel freight, vessel characteristics, vessel location, among others).

Using obtained data, a system can propose one or more of: spot contracts to accept or ports to call in which order. A system can determine vessel routing and speed. Using an agent-based model, a system can simulate quantities of interest such as fuel consumption or revenue across a portion of a, or an entire, fleet given multiple different assignment options. Using Monte Carlo methods taking into account uncertainty in weather forecasts, port delays, or other stochastic events, a system can simulate quantities of interest with uncertainty estimates. Taking into account these predicted quantities of interest, a system can recommend optimal decisions on vessel schedules, e.g., which contracts to accept, vessel assignment options, port calls, or vessel routing.

Similar to the simulation 1204, the workflow 1300 can include the simulation 1304 for simulating an effect within a network of a tramping vessel being assigned to a route or to carry cargo from a first location to a second location. For example, a first tramp vessel can be scheduled to carry a cargo to point B obviating a previously scheduled vessel from carrying that same cargo. Schedules can be optimized, as shown in optimization 1306, and as described in this document—e.g., to reduce a weighted sum, comparing one or more candidate networks, among others. The workflow 1300 can generate a recommended schedule 1308 indicate a schedule for one or more tramp ships. The schedule can indicate at least a portion of an optimal shipping network that includes a tramp vessel as one vessel with a route.

An example process performed by systems described in this document can include one or more of: 8. determining, generating, and providing a display of a current fleet status (e.g., including vessel locations or vessel assignments); 9. determining, generating, and providing details of contracts available; 10. determining, generating, and providing recommendations for vessel routing and speed, e.g., with notifications of recommended changes to route or speed; 11. determining, generating, and providing recommended options for vessel schedules (e.g., port calls, arrival times, commodities, and vessel assignments. Recommended options can include predicted quantities of interest, including uncertainty.); 12. providing an interface for a user to select a vessel schedule recommendation. Selected vessel schedule recommendation can instigate further actions by systems described herein, e.g., by transmitting one or more signals configured to adjust a shipping network-adjust ship route, adjust speed, add ships, accept contract, among others.

In some implementations, systems described automatically take action without user feedback. For example, a user can pre-approve one or more systems to take action. After a system generates one or more recommendations, the system can determine one or more primary recommendations and perform one or more actions to implement the one or more primary recommendations in a shipping network. The one or more primary recommendations can be a number of top ranked recommendations based on one or more objective functions and quantities of interest.

An example display interface generated and provided by systems described in this document is shown in FIG. 14. A display interface generated and displayed by a system for tramp shipping vessel scheduling optimization can include one or more of: a list of charters (e.g., assigned charters-origin, destination, ETA, customer, vessel identifier, among others, unassigned charters-origin destination, desired ETA, customer, contract value); a list of vessels (e.g., including vessels assigned to specific service routes, vessel status data, fuel consumption, speed, ETA, among others); a map (e.g., showing color coded vessels, such as red indicating cargo full, yellow indicating in route to cargo, green indicating unassigned); a list of recommended vessel schedules (e.g., vessel A assigned to charter X, vessel B assigned to charter Y); predicted metrics (e.g., 7 day fuel consumption, 7 day revenue, number of delayed shipments, over time. Metrics can be displayed using one or more plots. Plots can include uncertainty generated by one or more systems described in this document.).

A number of implementations have been described. Nevertheless, it will be understood that various modifications can be made without departing from the spirit and scope of the disclosure. For example, various forms of the flows shown above can be used, with operations re-ordered, added, or removed.

Implementations of the subject matter and the functional operations described in this specification can be implemented in digital electronic circuitry, in tangibly-embodied computer software or firmware, in computer hardware, including the structures disclosed in this specification and their structural equivalents, or in combinations of one or more of them. Implementations of the subject matter described in this specification can be implemented as one or more computer programs, i.e., one or more modules of computer program instructions encoded on a tangible non-transitory program carrier for execution by, or to control the operation of, a data processing apparatus. Alternatively, or in addition, the program instructions can be encoded on an artificially-generated propagated signal, e.g., a machine-generated electrical, optical, or electromagnetic signal, that is generated to encode information for transmission to a suitable receiver apparatus for execution by a data processing apparatus. One or more computer storage media can include a machine-readable storage device, a machine-readable storage substrate, a random or serial access memory device, or a combination of one or more of them.

The term “data processing apparatus” refers to data processing hardware and encompasses all kinds of apparatus, devices, and machines for processing data, including by way of example a programmable processor, a computer, or multiple processors or computers. The apparatus can be or include special purpose logic circuitry, e.g., a field programmable gate array (“FPGA”) or an application-specific integrated circuit (“ASIC”). The apparatus can optionally include, in addition to hardware, code that creates an execution environment for computer programs, e.g., code that constitutes processor firmware, a protocol stack, a database management system, an operating system, or a combination of one or more of them.

A computer program, which may also be referred to or described as a program, software, a software application, a module, a software module, a script, or code, can be written in any form of programming language, including compiled or interpreted languages, or declarative or procedural languages, and it can be deployed in any form, including as a stand-alone program or as a module, component, subroutine, or other unit suitable for use in a computing environment. A computer program may, but need not, correspond to a file in a file system. A program can be stored in a portion of a file that holds other programs or data, e.g., one or more scripts stored in a markup language document, in a single file dedicated to the program in question, or in multiple coordinated files, e.g., files that store one or more modules, sub-programs, or portions of code. A computer program can be deployed to be executed on one computer or on multiple computers that are located at one site or distributed across multiple sites and interconnected by a communication network.

The processes and logic flows described in this specification can be performed by one or more programmable computers executing one or more computer programs to perform functions by operating on input data and generating output. The processes and logic flows can be performed by, and apparatus can also be implemented as, special purpose logic circuitry, e.g., a field programmable gate array (“FPGA”) or an application-specific integrated circuit (“ASIC”).

Computers suitable for the execution of a computer program include, by way of example, general or special purpose microprocessors or both, or any other kind of central processing unit. Generally, a central processing unit will receive instructions and data from a read-only memory or a random access memory or both. The essential elements of a computer are a central processing unit for performing or executing instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. A computer can be embedded in another device, e.g., a mobile telephone, a smart phone, a headset, a personal digital assistant (“PDA”), a mobile audio or video player, a game console, a Global Positioning System (“GPS”) receiver, or a portable storage device, e.g., a universal serial bus (“USB”) flash drive, to name just a few.

Computer-readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, implementations of the subject matter described in this specification can be implemented on a computer having a display device, e.g., a liquid crystal display (“LCD”), an organic light emitting diode (“OLED”) or other monitor, for displaying information to the user and a keyboard and a pointing device, e.g., a mouse or a trackball or a touchscreen, by which the user can provide input to the computer. Other kinds of devices can be used to provide for interaction with a user as well. For example, feedback provided to the user can be any form of sensory feedback, e.g., visual feedback, auditory feedback, or tactile feedback; and input from the user can be received in any form, including acoustic, speech, or tactile input. In some examples, a computer can interact with a user by sending documents to and receiving documents from a device that is used by the user; for example, by sending web pages to a web browser on a user's device in response to requests received from the web browser.

Implementations of the subject matter described in this specification can be implemented in a computing system that includes a back-end component, e.g., as a data server, or that includes a middleware component, e.g., an application server, or that includes a front-end component, e.g., a client computer having a graphical user interface or a Web browser through which a user can interact with an implementation of the subject matter described in this specification, or any combination of one or more such back-end, middleware, or front-end components. The components of the system can be interconnected by any form or medium of digital data communication, e.g., a communication network. Examples of communication networks include a local area network (“LAN”) and a wide area network (“WAN”), e.g., the Internet.

The computing system can include clients and servers. A client and server are generally remote from each other and typically interact through a communication network. The relationship of client and server arises by virtue of computer programs running on the respective computers and having a client-server relationship to each other. In some implementations, a server transmits data, e.g., an Hypertext Markup Language (“HTML”) page, to a user device, e.g., for purposes of displaying data to and receiving user input from a user device, which acts as a client. Data generated at the user device, e.g., a result of user interaction with the user device, can be received from the user device at the server.

While this specification contains many specific implementation details, these should not be construed as limitations on the scope of what may be claimed, but rather as descriptions of features that may be specific to particular implementations. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

In each instance where an HTML file is mentioned, other file types or formats may be substituted. For instance, an HTML file may be replaced by an XML, JSON, plain text, or other types of files. Moreover, where a table or hash table is mentioned, other data structures, such as spreadsheets, relational databases, or structured files, may be used.

Particular implementations of the invention have been described. Other implementations are within the scope of the following claims. For example, the operations recited in the claims, described in the specification, or depicted in the figures can be performed in a different order and still achieve desirable results. In some cases, multitasking and parallel processing may be advantageous.

1. A method comprising:
generating simulated shipping routes, including a first simulated route under a first environmental condition and a second simulated route under a second environmental condition;
generating an uncertainty score for each of the one or more simulated shipping routes;
determining, using the uncertainty scores, (1) a first ship to traverse the first simulated route of the simulated shipping routes and (2) a second ship to traverse the second simulated route of the simulated shipping routes;
generating two or more candidate networks, wherein a first candidate network of the two or more candidate networks includes an indication of (1) the first ship to traverse the first simulated route and (2) the second ship to traverse the second simulated route;
comparing the first candidate network and another candidate network of the two or more candidate networks under two or more different environmental conditions;
determining, using the comparison, an optimal candidate network of the two or more candidate networks; and
providing data indicating the optimal candidate network to the one or more ships.

2. The method of claim 1, wherein the two or more different environmental conditions are generated using an ocean model that predicts current or weather events.

3. The method of claim 1, wherein the simulated shipping routes include one or more shipping ports.

4. The method of claim 1, comprising:
determining cargo to be transported by the first ship and the second ship.

5. The method of claim 1, comprising:
obtaining data from the first ship prior to determining the first ship to traverse the first shipping route of the one or more simulated shipping routes.

6. The method of claim 5, wherein the data obtained from the first ship includes data indicating one or more locations along the first shipping route.

7. The method of claim 5, wherein the data obtained from the first ship includes route preferences of the first ship.

8. The method of claim 1, wherein generating an uncertainty score for each of the one or more simulated shipping routes comprises:
generating an uncertainty score for the first simulated route including generating one or more distributions representing the first environmental condition of the first simulated route.

9. The method of claim 8, wherein the first environmental condition of the first simulated route include wait times at port or weather events.

10. The method of claim 1, comprising:
generating one or more distributions representing an effect of environmental conditions of the two or more different environmental conditions on the first simulated route and the second simulated route.

11. The method of claim 1, comprising:
comparing a previously determined network and the optimal candidate network, wherein the previously determined network includes one or more of (1) a route of the first ship different than the first simulated route or (2) a route of the second ship different than the second simulated route.

12. The method of claim 11, comprising:
performing the comparison of the previously determined network and the optimal candidate network under the two or more different environmental conditions.

13. The method of claim 1, wherein the two or more different environmental conditions include nominal and off-nominal conditions.

14. A system comprising one or more computers and one or more storage devices on which are stored instructions that are operable, when executed by the one or more computers, to cause the one or more computers to perform operations comprising:
generating simulated shipping routes, including a first simulated route under a first environmental condition and a second simulated route under a second environmental condition;
generating an uncertainty score for each of the one or more simulated shipping routes;
determining, using the uncertainty scores, (1) a first ship to traverse the first simulated route of the simulated shipping routes and (2) a second ship to traverse the second simulated route of the simulated shipping routes;
generating two or more candidate networks, wherein a first candidate network of the two or more candidate networks includes an indication of (1) the first ship to traverse the first simulated route and (2) the second ship to traverse the second simulated route;
comparing the first candidate network and another candidate network of the two or more candidate networks under two or more different environmental conditions;
determining, using the comparison, an optimal candidate network of the two or more candidate networks; and
providing data indicating the optimal candidate network to the one or more ships.

15. The system of claim 14, wherein the two or more different environmental conditions are generated using an ocean model that predicts current or weather events.

16. The system of claim 14, wherein the simulated shipping routes include one or more shipping ports.

17. The system of claim 14, the operations comprising:
determining cargo to be transported by the first ship and the second ship.

18. The system of claim 14, the operations comprising:
obtaining data from the first ship prior to determining the first ship to traverse the first shipping route of the one or more simulated shipping routes.

19. The system of claim 18, wherein the data obtained from the first ship includes data indicating one or more locations along the first shipping route.

20. One or more non-transitory computer storage media encoded with instructions that, when executed by one or more computers, cause the one or more computers to perform operations comprising:
generating simulated shipping routes, including a first simulated route under a first environmental condition and a second simulated route under a second environmental condition;
generating an uncertainty score for each of the one or more simulated shipping routes;
determining, using the uncertainty scores, (1) a first ship to traverse the first simulated route of the simulated shipping routes and (2) a second ship to traverse the second simulated route of the simulated shipping routes;
generating two or more candidate networks, wherein a first candidate network of the two or more candidate networks includes an indication of (1) the first ship to traverse the first simulated route and (2) the second ship to traverse the second simulated route;
comparing the first candidate network and another candidate network of the two or more candidate networks under two or more different environmental conditions;
determining, using the comparison, an optimal candidate network of the two or more candidate networks; and
providing data indicating the optimal candidate network to the one or more ships.
